(19) United States
(12) Patent Application Publication
(10) Pub. No.: US 2025/0110191 A1
(43) Pub. Date: Apr. 3, 2025

(54) Transformer Test System and Method

(71) Applicant: AVO Multi-Amp Corporation d/b/a Megger, Dallas, TX (US)

(72) Inventors: Oleh Iwanusiw, Toronto (CA); Vince Oppedisano, Richmond Hill (CA); Kristopher Neild, Lansdale, PA (US); Roman Nykyforchyn, Phoenixville, PA (US)

(21) Appl. No.: 18/902,120

(22) Filed: Sep. 30, 2024

Related U.S. Application Data
(60) Provisional application No. 63/586,753, filed on Sep. 29, 2023.

(51) Int. Cl. G01R 31/62; G01R 25/00; G01R 27/08

(52) U.S. Cl. CPC G01R 31/62; G01R 25/00; G01R 27/08

(57) ABSTRACT

A transformer windings impedance meter. The meter comprises a switching matrix; a plurality of field effect transistors (FETs); a measurement circuit; a test output circuit; and a processor coupled to the switching matrix, the plurality of FETs, the measurement circuit, and the test output circuit, wherein the processor is configured to configure the switching matrix in a first configuration, apply a short circuit to a first side of a transformer, where the short circuit is completed through at least one of the plurality of FETs, apply a first alternating current (AC) excitation to a second side of the transformer, while continuing to apply the first AC excitation to the second side of the transformer, measure a first voltage and a first current in the second side of the transformer, and determine an impedance of the second side of the transformer based on the first voltage and the first current.

### CROSS-REFERENCE TO RELATED APPLICATIONS

This application claims priority to U.S. Provisional Application No. 63/586,753 filed Sep. 29, 2023 by Oleh Iwanusiw, et al. entitled, “Transformer Test System and Method” (Attorney Docket No. 4100-06000), which is incorporated by reference herein as if reproduced in its entirety.

### BACKGROUND

The electrical power system in the United States generates three-phase alternating current (AC) electrical power. Each power phase is 120 degrees out of phase, plus or minus, with the other two power phases. The voltage of any phase oscillates sinusoidally between positive voltage and negative voltage. It is more efficient to transmit electrical power at high voltage levels than at low voltage levels. Electrical power may be generated as three-phase AC power at moderate voltage levels in the 12 thousand volt (kV) to 25 kV range. The voltage level may be stepped up to the 110 KV to 1000 kV range using a transformer for transmission over long transmission lines, in order to decrease transmission line power loss. The transmission line voltage may be stepped down, using a transformer at a substation, to the 12 kV to 35 kV range for local distribution. The local distribution voltage level may be further stepped down through one or more transformer stages to provide 120 volt AC power to the home and office.

Power system transformers may comprise three pairs of wire windings, one pair of windings for each phase. Each pair of wire windings is constructed so that an alternating electric voltage in a primary winding creates a fluctuating electro-magnetic field that couples into the secondary winding, thereby inducing a corresponding alternating electric voltage in the secondary winding. Typically, the primary and secondary windings are wound on a common core that improves the efficiency of the transformer by concentrating the electro-magnetic field within the common core, thereby improving the coupling between the primary and secondary windings. In an ideal transformer, the voltage in the secondary winding Vₛ is proportional to the voltage in the primary winding Vₚ, where the proportionality is mediated by the ratio of the number of wire turns in the secondary winding Nₛ to the number of wire turns in the primary winding Nₚ: Vₛ=Vₚ (Nₛ/Nₚ). In an ideal transformer, the current in the secondary winding Iₛ is proportional to the current in the primary winding Iₚ, where the proportionality is mediated by the ratio of the number of wire turns in the primary winding Nₚ to the number of wire turns in the secondary winding Nₛ: Iₛ=Iₚ (Nₚ/Nₛ). The performance of power system transformers may change as insulation of the windings or the magnetic properties of the core deteriorate. This deterioration of the insulation may lead to a dissipation factor (DF) that is greater than zero. In some contexts, the dissipation factor may be referred to as the insulation power factor. In practical power system components, the dissipation factor is greater than zero, but by a tolerable fraction of a percent. For example, a dissipation factor value at 20 degrees Celsius for a new power distribution transformer winding may be about 0.001. A dissipation factor value of 0.01 may be grounds for an alert or warning. Similarly, the core may have losses in the form of hysteresis or eddy currents. Such losses will change if the core laminations become shorted. Shorted turns on either winding will also cause losses in the form of eddy currents.

Theoretically, power-out equals power-in in a transformer. However, even good performing transformers may have less than 100% efficiency. The lost power, be it in the insulation of the transformer or in the magnetic circuit of the core, may manifest itself in the form of heat. Power may also be lost through leakage current paths that do not transfer to the secondary winding, but rather through the transformer's insulation back to ground at the power-in source. The ratio of number of turns in the secondary winding and the number of turns in the primary winding may change if a turn shorts at a point of insulation breakdown on either winding. If the transformer is faulty, the lost power may cost money to the electric utility company that operates the transformer. Further, lost power may indicate a more serious problem, for example, overheating, that if left unattended may result in catastrophic damage to or failure of the transformer and loss of power to customers.

A wide variety of power system transformer configurations is known, and some transformers may vary somewhat from the general description above. Typically, power transformers are connected in three-phases in either a delta or wye connection. The reasons for choosing a delta or wye configuration may include that wye configurations allow for three independent voltages, while delta configurations allow the windings to combine to provide a common voltage, thus providing greater stability. In a wye configuration there may be an extra node commonly referred to as neutral. Therefore, in a wye to wye configuration, there may be eight nodes, while in a delta to delta configuration there may only be six nodes. Some transformers may be single-phase transformers. Some transformers may be auto-transformers. Some transformers may have taps. The external connections to power distribution transformer windings may be provided via bushings. In some embodiments, bushings include ceramic insulators.

Testing of power system transformers may be conducted by connecting a test set to the windings of the power system transformers and exciting the primary winding or the secondary winding with electrical signals, that may be direct current (DC) or alternating current (AC). Testing may be conducted on one transformer phase at a time, or may be conducted concurrently on multiple phases of the transformer.

### SUMMARY

In an embodiment, a transformer windings resistance meter is disclosed. The meter comprises a switching matrix; a measurement circuit; a test output circuit; and a processor coupled to the switching matrix, measurement circuit, and test output circuit. The processor is configured to configure the switching matrix in a first configuration; apply a first energization output to a first side of a transformer; while continuing to apply the first energization to the first side of the transformer, apply a second energization output to a first phase of a second side of the transformer; and, while continuing to apply the first energization output to the first side of the transformer and while continuing to apply the second energization output to the first phase of the second side of the transformer, measure a first voltage and a first current on the first phase of the second side of the transformer. The processor is further configured to, based on the first voltage and the first current, determine a first winding resistance of the first phase of the second side of the transformer; while continuing to apply the first energization output to the first side of the transformer, remove the second energization output from the first phase of the second side of the transformer; and, while continuing to apply the first energization output to the first side of the transformer and after removing the second energization output from the first phase of the second side of the transformer, apply a third energization output energization output to a second phase of the second side of the transformer. The processor is further configure to, while continuing to apply the first energization output to the first side of the transformer and continuing to apply the third energization output to the second phase of the second side of the transformer, measure a second voltage and a second current on the second phase of the second side of the transformer; and, based on the second voltage and the second current, determine a second winding resistance of the second phase of the second side of the transformer.

In another embodiment, a transformer windings impedance meter is disclosed. The meter comprises a switching matrix; a plurality of field effect transistors (FETs); a measurement circuit; a test output circuit; and a processor coupled to the switching matrix, the plurality of FETs, the measurement circuit, and the test output circuit, wherein the processor is configured to configure the switching matrix in a first configuration, apply a short circuit to a first side of a transformer, where the short circuit is completed through at least one of the plurality of FETs, apply a first alternating current (AC) excitation to a second side of the transformer, while continuing to apply the first AC excitation to the second side of the transformer, measure a first voltage and a first current in the second side of the transformer, and determine an impedance of the second side of the transformer based on the first voltage and the first current.

In yet another embodiment, a method for measuring no-load losses in a transformer is disclosed. The method comprises exciting a first side of the transformer by a transformer tester with a first excitation output, where the first excitation output is a first alternating current (AC) voltage and at a first frequency, wherein a second side of the transformer is open; measuring a first current in the first side of the transformer and a first phase angle of the first current relative to the first AC voltage by the transformer tester; and exciting the first side of the transformer by the transformer tester with a second excitation output, wherein the second excitation output is a second AC voltage and a second frequency. The method further comprises measuring a second current in the first side of the transformer and a second phase angle of the second current relative to the second AC voltage by the transformer tester; and determining eddy current losses in the transformer by the transformer tester based on the first AC voltage, the first frequency, the first current, the first phase angle, the second AC voltage, the second frequency, the second current, and the second phase angle.

Also described herein is a system and method for transformer turns ratio measurement. A turns ratio meter may be configured to perform step-down testing using a switched DC excitation signal applied to the higher voltage winding. The results of the step-down testing may be used to determine characteristics of the transformer, e.g., excitation current, excitation losses, phase angle, etc. Based on the results of the step-down testing and the determined characteristics, the turns ratio meter may perform step-up testing of the transformer using switched DC applied to the lower voltage winding. The test may be performed without rearranging any cables of the turns ratio meter connected to the transformer. Using the results of the step-down and step-up testing, refined using the determined characteristics, a more accurate turns ratio may be determined and provided to a tester.

The step-up and step-down testing may be performed using three phase simultaneous excitation/measurements using a switching matrix to switch between down excitation and up excitation to provide transformer phase angle, turns ratio and core balance. In this process, the collection of multiple ratio measurement data sets, phase angle calculations, core balance calculations, and identification of neutral being present provides the ability to calculate for user presentation more accurate transformer ratio results. The product/instrument control of the implemented excitation and measurement circuitry also supports single phase ratio basic voltage ratio measurement determinations. These and other features will be more clearly understood from the following detailed description taken in conjunction with the accompanying drawings and claims.

### BRIEF DESCRIPTION OF THE DRAWINGS

For a more complete understanding of the present disclosure, reference is now made to the following brief description, taken in connection with the accompanying drawings and detailed description, wherein like reference numerals represent like parts.

FIG. 1 is a diagram of an embodiment of a transformer turns ratio measurement using a turns ratio meter.

FIG. 2 is a diagram of an embodiment of a turns ratio meter according to an embodiment of the disclosure.

FIG. 3 is a diagram of an embodiment of a method for transformer turns ratio testing according to an embodiment of the disclosure.

FIG. 4 is a diagram of an embodiment of a system for transformer turns ratio measurement according to an embodiment of the disclosure.

FIG. 5 is a block diagram of a transformer tester according to an embodiment of the disclosure.

FIG. 6 is a block diagram of another transformer tester according to an embodiment of the disclosure.

FIG. 7A and FIG. 7B is a flow chart of a method according to an embodiment of the disclosure.

FIG. 8 is a flow chart of another method according to an embodiment of the disclosure.

FIG. 9A and FIG. 9B is a flow chart of yet another method according to an embodiment of the disclosure.

FIG. 10A, FIG. 10B, FIG. 10C, and FIG. 10D are illustrations of a transformer magnetization curve according to an embodiment of the disclosure.

### DETAILED DESCRIPTION

Described herein is a system and method for transformer turns ratio measurement. In an embodiment, a turns ratio meter may be connected to each phase of each set of windings. Step-down testing may be performed on the transformer followed by step-up testing. The excitation voltage used in testing may be a DC square-wave. The excitation voltage may be relatively low, between 1 and 48 volts. The step-down and step-up testing may be performed several times with different voltages and/or frequencies. Excitation losses of the transformer may be determined based upon the multiple step-down and step-up tests. The step-down and step-up testing may be performed without reconfiguring the test leads on the transformer. The testing may be performed on a single phase of the transformer or all three phases of the transformer simultaneously. The turns ratio of the transformer may be accurately determined using the results of the step-down and step-up testing and the calculated excitation losses.

Further described herein is a transformer tester that is configured to determine one or more of (A) winding resistance of one or more windings of a transformer, (B) short-circuit impedance of a transformer, (C) losses of a transformer (e.g., hysteresis losses and eddy current losses), and (D) symmetric components of a transformer. The winding resistance of the transformer is determined by energizing a first side of the transformer (e.g., saturating the core of the transformer) and then determining the winding resistance of each of the windings of a second side of the transformer while maintaining the core energized by the first side of the transformer. This process enables rapid determination of windings resistances, because it is not necessary to charge and discharge the transformer core between each separate winding resistance measurement. This can support successful “heat run tests” which are subject to challenging time constraints before the transformer cools off. The short-circuit impedance of the transformer is conducted, in part, by providing a short-circuit within the transformer tester itself, for example via field effect transistors (FETs) in a shorting circuit of the transformer tester. The losses of a transformer can be determined by exciting the transformer with different voltages and different frequencies, whereby to better separate eddy current losses from hysteresis losses.

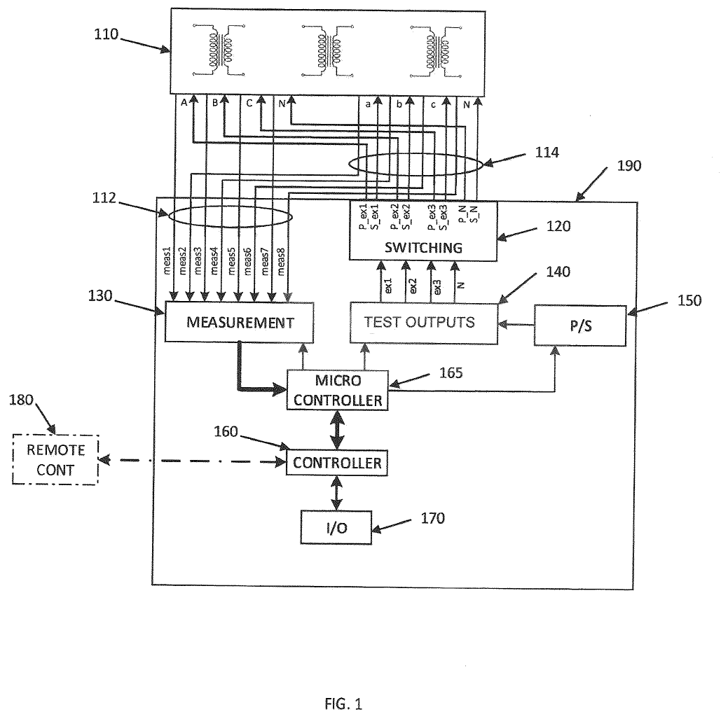

FIG. 1 is a diagram of an embodiment of a turns ratio measurement using a turns ratio meter 190. The turns ratio meter 190 may be self-contained, that is the components for testing may all be contained within a single case. The turns ratio meter 190 may be ruggedized and shielded appropriately to provide service in the harsh electrical environment of a power generation and/or power distribution station and exposed to the weather. During testing, a turns ratio meter 190 may be connected to a transformer 110. The turns ratio meter 190 may be connected to the transformer 110 by connectors and cables. The connector may, for example, be a cannon plug, bushing clamp, or other connector for electrically coupling the turns ratio meter 190 to the transformer 110. The connection provides an electrical path from the turns ratio meter 190 to the transformer 110.

In this embodiment, transformer 110 may be a three-phase transformer. In other embodiments, transformer 110 may be a single-phase transformer or a two-phase transformer, or some other electrical component with windings. The transformer 110 may be coupled to the turns ratio meter 190 by measurement connections 112 and test output connections 114. Test output connections 114 may be stimulus connections simultaneously connected to each phase and neutral of transformer 110 on both the primary and secondary sides of transformer 110. Measurement connections 112 may be measurement connections connected to each phase and neutral of transformer 110 on both the primary and secondary sides of transformer 110. The measurement connections 112 and test output connections 114 may be configured as Kelvin connections, e.g., the contacts in measurement connections 112 and test output connections 114 may be configured to reduce the effect of the resistance of the contacts and wires coupling the transformer 110 and the turns ratio meter 190.

The test output connections 114 from the transformer 110 to the turns ratio meter 190 may be coupled to a switching matrix 120 within the turns ratio meter 190. The switching matrix 120 may contain switches that are controlled by controller 160 and/or microcontroller 165. The switches may be mechanical switches, transistor switches, or any other type of switch that may be used for switching excitation signals from the turns ratio meter 190 to the transformer 110. The switching matrix 120 may be controlled to cause the turns ratio meter 190 to excite the high side or the low side of the transformer 110 without rearranging cables between the turns ratio meter 190 and the transformer 110.

The switching matrix 120 may also be coupled to a test output circuit 140. The connections between switching matrix 120 and test output circuit 140 may each correspond to a phase or neutral connection to the transformer 110. The switching matrix 120 may be configured to provide a single phase excitation signal or simultaneously provide an excitation signal to all three phases of the transformer 110.

Controller 160 and/or microcontroller 165 may control the switching matrix 120 to apply excitation signals received from the test output circuit 140 to the transformer 110. The test output circuit 140 may receive electrical power from a power supply 150. The power supply 150 may be a variable power supply or a fixed power supply configured to provide AC or DC signals for use in exciting the transformer 110. Test output circuit 140 may condition the electrical signals received from the power supply 150 based upon the requirements of transformer 110 or other factors. In some cases, the electrical signals received from the power supply 150 may not require further conditioning.

In some embodiments, the test output circuit 140 may excite the transformer windings using square-wave excitation. The square-wave may be a reversible DC square-wave. The excitation may be varied from 1 volt to 48 volts, and reversed to −48 volts to −1 volt. The square-wave may vary in amplitude based upon the characteristics of the power supply 150 and/or test output circuit 140. In some embodiments, the test output circuit 140 may excite the transformer windings using sine wave excitation, e.g., alternating current (AC). In some embodiments, the excitation signal, either AC or switched DC, may be provided at various frequencies, for example the frequency of the excitation signal may equal the power line frequency, harmonics, and/or sub-harmonics of the power line or source (not pictured) connected to the transformer 110.

The test output circuit 140 may provide single-phase excitation and/or three-phase excitation to the transformer under test. All the signals received from the transformer 110 may be continuously measured by the measurement circuit 130. Controller 160 and/or microcontroller 165 may control the switching matrix 120 to transmit signals received from the transformer 110 to the measurement circuit 130 for measurement. The single-phase excitation may be used for single-phase testing and/or three-phase testing. Testing three-phase transformers using single-phase excitation may be accomplished by applying the single-phase excitation to each phase of the transformer, one phase at a time. The single-phase excitation may be applied to one set of windings (e.g., primary) and a resulting voltage may be measured at the other set of windings (e.g., secondary). The turns ratio meter 190 may measure voltage, current, active power, and reactive power using the single-phase excitation.

In an embodiment, the test output circuit 140 may be configured to provide three-phase excitation. The three-phase excitation may be highly symmetric with respect to magnitude and phase, e.g., each phase is 120 degrees out of phase from the next phase. Three-phase testing using three-phase excitation may be accomplished by simultaneously applying excitation to each phase of the transformer. The three-phase excitation may be applied to one set of windings (e.g., primary) and resulting voltages may be measured at the other set of windings (e.g., secondary). Testing with three-phase excitation allows the transformer to be tested under circumstances that are very similar to circumstances that the transformer would experience under normal operating conditions. Three-phase testing improves the accuracy of measurements of the characteristics of the transformer, e.g. ratio, phase, and/or core loss as experienced while all three phases are excited.

The turns ratio meter 190 may be configured to calculate the symmetrical components of excitation signals applied to each set of windings of the transformer 110. The symmetrical components of the signal may be referred to herein as negative or positive or zero components. Negative components may also be referred to as inverse components and positive components may also be referred to as direct components. Comparing the applied positive sequence voltage of the excited winding of the transformer 110 with the positive sequence voltage of another winding of the transformer 110 may increase the accuracy of the measured turns ratio, as well as any measured phase displacement of the transformer 110. The turns ratio meter 190 may determine problems with the transformer 110 by comparing the applied negative and zero sequence voltage to the excited winding of the transformer 110 with the negative sequence voltage of another winding of the transformer 110.

For example, in a well-balanced three-phase system, the positive sequence is very close to the average of each of the three phases measured individually. The negative sequence of the three-phase system is approximately the average of the differences between each of the three phases individually. Any detection of a negative sequence may indicate a difference between the individual phases, which is indicative of unmatched turn ratios, different core losses, shorted turns, or other problems in a transformer. A negative sequence may be undesirable due to resulting losses of efficiency of the transformer. In some embodiments, detection of a negative sequence above a threshold may be an indicator of the need to replace a transformer under test. The magnitude of the negative sequence component and the zero sequence component may be indicative of a likely problem with the transformer. These values are obtainable from a three-phase test using very symmetrical three-phase excitation.

Input/Output (I/O) component 170 may include input and output devices for interacting with the turns ratio meter 190. For example, I/O component 170 may include a keyboard, touch screen, video display, microphone, speakers, and/or other components for interacting with the turns ratio meter 190, e.g., controlling testing and/or displaying results of testing. The turns ratio meter 190 may be optionally coupled to a printer (not pictured) at a test location, and the test results may be printed out on-location and left with and/or used by an electrical power operating company or other appropriate entity. Results of testing may be stored in a local or remote data store (not pictured) for comparison with later test results. Optionally, a remote control 180 may be used to interact with turns ratio meter 190. For example, a wireless and/or wired connection may be made between remote control 180 and the controller 160. A user may interact with the turns ratio meter 190 from a remote location using the remote controller 180.

The turns ratio meter 190 may be employed for testing power system components other than power system transformers, including instrument transformers, cables, generators, electric motors, rotating machines, batteries, protection relays, circuit breakers, and others, in some cases after making appropriate modifications to the test output circuit 140, switching matrix 120, and/or measurement circuit 130. The turns ratio meter 190 may further be configured to measure other characteristics of the transformer 110 for use in troubleshooting and maintaining the transformer 110. For example the turns ratio meter 190 may be configured to detect problems with the core and/or windings of the transformer 110.

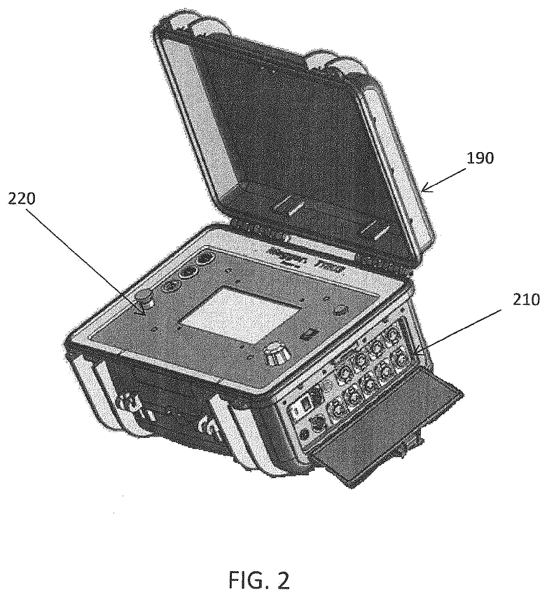

FIG. 2 is a diagram of an embodiment of a turns ratio meter 190. The turns ratio meter 190 may include a connection panel 210. The connection panel 210 may include a plurality of connectors for connecting test leads from the turns ratio meter 190 to a transformer under test, e.g., transformer 110. The connection panel 210 may be part of measurement connections 112 and test output connections 114. There may be one connector on connection panel 210 for each phase of the transformer including neutral. There may also be a connector for a remote controller to interact with the turns ratio meter 190. Further there may be a connector for programming the turns ratio meter 190. The programming may include firmware, operating system, and/or software updates to the turns ratio meter 190. In some embodiments, the connectors may be combined into a single connector or divided among any number of connectors. In some embodiments, the connectors may be physical hardwired connectors. In some embodiments the connectors may be wireless connections. The turns ratio meter 190 may also include an I/O panel 220. The I/O panel 220 may include various I/O devices. For example, a touchscreen interface, control knob, switches, keyboards, and/or other input/output devices. In some embodiments, there may be other panels and/or the connection panel 210 and I/O panel 220 may be combined in a single panel.

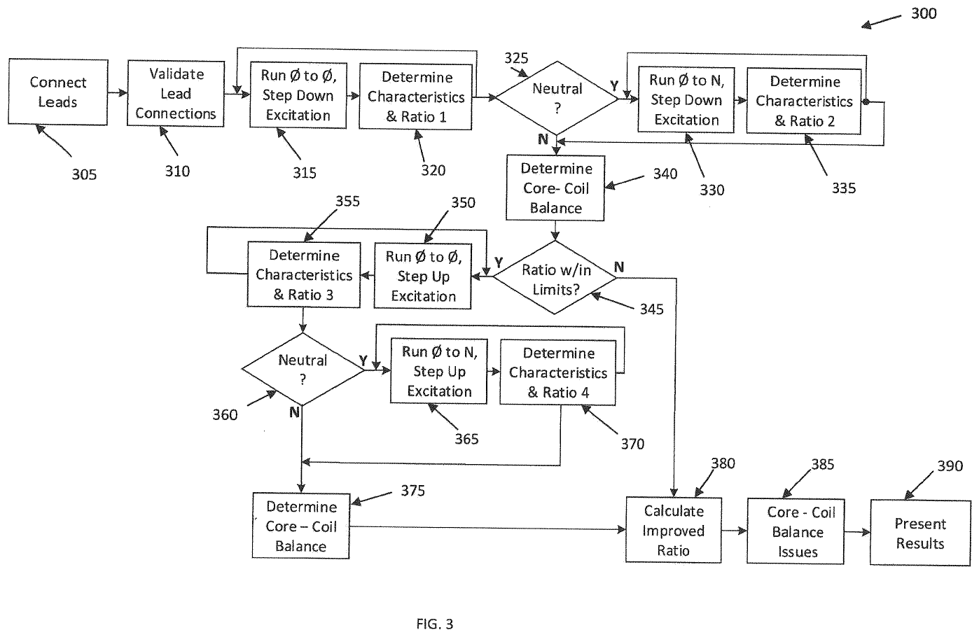

FIG. 3 is a flow diagram of an embodiment of a method 300 for transformer turns ratio testing. The method may begin at step 305 when test leads are connected from a transformer turns ratio meter, e.g. turns ratio meter 190, to a transformer under test, e.g., transformer 110. If the transformer is a three-phase transformer, test leads may be connected between each phase and neutral on both the primary and secondary sides of the transformer. The transformer turns ratio meter may perform a setup test as part of step 310. The setup test may validate that the test leads are properly connected between the turns ratio meter and the transformer. The setup test may apply small voltages to the test leads to ensure the transformer turns ratio meter has been properly connected to the transformer under test.

The method may continue at step 315 where the turns ratio meter may perform phase to phase step-down testing on the transformer. Step-down testing may include applying an excitation signal to the primary windings of a step-down transformer and measuring the output at the secondary windings, or applying an excitation signal to the secondary windings of a step-up transformer and measuring the output of the primary windings. The excitation signal may be applied to one phase at a time or to all three phases simultaneously. A step-down test may apply a voltage as an input to the transformer, and measure a lower, stepped-down, voltage as an output from the transformer. For example, if testing a step-down transformer, 20 volts may be applied to the primary windings and 2 volts may be measured at the secondary windings. Based upon a ratio of the input voltage (20 volts), and the measured output voltage (2 volts), the transformer turns ratio may be estimated as 10 to 1.

The excitation signal used for excitation of the transformer during step-down testing may be determined in several ways. The excitation signal may be programmed by a user of the turns ratio meter, the excitation signal may be determined by the turns ratio meter based upon characteristics of the transformer entered at the I/O component of the turns ratio meter, and/or the excitation signal may be incrementally increased or decreased within the limits of the excitation and measurement circuits of the turns ratio meter. The characteristics of the transformer entered at the I/O component may be retrieved from a faceplate of the transformer. The step-down testing may be repeated several times with varying signal characteristics, e.g., different voltages and/or frequencies, used during each of the repeated step-down tests. The step-down testing may be accomplished using a square-wave, e.g., switched DC, as an excitation signal. A Fourier transform and/or Laplace transform may be used to determine sine wave characteristics of the applied and measured square-wave. The sine wave characteristics may be used in determining the transformer characteristics, e.g., excitation losses. Accurate transformer characteristics allow for corrections to be made to the measured output of the transformer under test and improve the accuracy of the transformer turn ratio estimate.

At step 320, the turns ratio meter may determine transformer characteristics of the transformer under test that affect measurements taken during testing. The turns ratio meter may be configured to apply corrections to the measurements taken during the step-up and step-down testing based on the transformer characteristics. For example, during excitation of the transformer, excitation loses, or no-load losses, may be experienced. Excitation losses may include core loss, dielectric loss, and copper loss in the windings due to the excitation current. The excitation losses may be the result of the current needed to energize the core of the transformer. The excitation losses may remain constant whether or not a load is attached to the transformer. Excitation losses may be determined by performing step-up and/or step-down testing using several different excitation voltages. Based on the results of the several tests using the varying excitation voltages, a correction factor may be determined to account for excitation losses of the transformer.

Also at step 320, the turns ratio meter may estimate the turns ratio of the transformer under test using the measurements from the step-down test and the determined transformer characteristics, e.g., excitation losses, phase angle of the various phases, and/or other characteristics that may affect the accuracy of the measurements.

At step 325, the turns ratio may determine if a neutral connection has been made between the turns ratio meter and the transformer under test. If a neutral connection is not present, the test continues at step 340. If a neutral connection is present, the test may continue at step 330, where step-down testing is performed from phase to neutral. At step 335, the turns ratio meter may use the results of phase to neutral step-down testing to update the characteristics of the transformer that were previously determined at step 320 and update the estimated turns ratio that was previously determined at step 320.

At step 340, the turns ratio meter may use the results of the previous step-down testing to determine a core-coil balance of the transformer. Core-coil balance determination may include calculating the positive, negative, and zero components of the measured output of the step-down testing. The core coil-balance may be used to determine if there are problems in the windings or core of the transformer under test.

At step 345, the turns ratio meter may determine whether the previously estimated turns ratio is below a safety threshold for step-up testing. The safety threshold may be determined based upon a maximum voltage that may be measured by the turns ratio meter. During step-up testing, large voltages may result based upon the turns ratio of the transformer under test and the voltage applied. If the turns ratio is relatively high, and a relatively high voltage is applied to the transformer under test, the voltage that results during step-up testing may be too high for the turns ratio meter to measure safely. The resulting high voltage may cause damage to the turns ratio meter and/or result in unsafe working conditions for a user of the turns ratio meter.

If the estimated turns ratio of the transformer under test is above the safety threshold, the method continues at step 380 where an improved turns ratio is calculated based upon the results of previous step-down testing and the core-coil balance determined at step 340. At step 385, any core-coil balance issues may be determined based on the core-coil balance determined at step 340 At step 390, results of the testing are provided to a user of the turns ratio meter. The results may include any combination of phase angle of the transformer, an estimated turns ratio of the transformer, any core-coil balance issues, or any other data gathered and/or calculated during the testing of the transformer.

If the estimated turns ratio of the transformer under test is below the threshold, the method continues to step 350. At step 350, a voltage for step-up testing is determined. The voltage may be determined based upon the estimated turns ratio determined during the step-down testing and/or a maximum voltage that may be safely measured by the turns ratio meter.

Also at step 350, phase to phase step-up testing of the transformer under test is performed. Step-up testing may include applying an excitation signal to the primary windings of a step-up transformer and measuring the output at the secondary windings, or applying an excitation signal to the secondary windings of a step-down transformer and measuring the output of the primary windings. A step-up test may apply a voltage as an input to the transformer, and measure a higher, stepped-up, voltage as an output from the transformer. For example, if testing a step-down transformer, 2 volts may be applied to the secondary windings and 20 volts may be measured at the primary windings. Based upon a ratio of the input voltage (2 volts), and the measured output voltage (20 volts), the transformer turns ratio may be estimated as 10 to 1. The excitation signal may be applied to one phase at a time or to all three phases simultaneously. The voltage for step-up testing may be incrementally increased or decreased within the limits of the excitation and measurement circuits of the turns ratio meter. The step-up testing may be repeated several times with varying signal characteristics, e.g. different voltages and/or frequencies, used during each of the repeated step-up tests. The step-up testing may be accomplished using a square-wave, e.g., switched DC, as an excitation signal. A Fourier transform and/or Laplace transform may be used to determine sine wave characteristics of the applied and measured square-wave. The sine wave characteristics of the step-up testing may be used in conjunction with the sine wave characteristics determined during step-down testing to improve the accuracy of the calculations of the transformer characteristics, e.g., excitation losses.

At step 355, the turns ratio meter may determine transformer characteristics of the transformer under test that affect measurements taken during testing and determine the turns ratio of the transformer under test using any combination of the measurements from the step-up test performed at step 350, the determined transformer characteristics, e.g., excitation losses, and/or the results of the step-down testing. The transformer characteristics determined during step-down testing may be updated based on the results of the step-up testing. In some embodiments, the transformer characteristics determined during step-down testing may be used during step-up testing for improved accuracy. The turns ratio may be further determined by taking an average of the turns ratio determined at step 320, step 335 and/or the turns ratio determined as a result of the step-up test at step 355.

At step 360, the turns ratio may determine if a neutral connection has been made between the turns ratio meter and the transformer under test. If a neutral connection is not present, the test continues at step 375. If a neutral connection is present, the test may continue at step 365, where step-down testing is performed from phase to neutral. At step 370, the turns ratio meter may use the results of phase to neutral step-down testing to update the characteristics of the transformer that were previously determined at step 355 and update the estimated turns ratio that was previously determined at step 355.

At step 375, the turns ratio meter may use the results of the previous step-down testing to determine a core-coil balance of the transformer. Core-coil balance determination may include calculating the positive, negative, and zero components of the measured output of the step-down testing. The core coil-balance may be used to determine if there are problems in the windings or core of the transformer under test.

The method continues at step 380 where an improved turns ratio is calculated based upon the results of previous step-down testing and the core-coil balance determined at step 340. At step 385, any core-coil balance issues may be determined based on the core-coil balance determined at step 340. At step 390, results of the testing are provided to a user of the turns ratio meter. The results may include any combination of phase angle of the transformer, an estimated turns ratio of the transformer, any core-coil balance issues, or any other data gathered and/or calculated during the testing of the transformer.

In some embodiments, each time step-up and step-down testing is performed, the results of that particular test may be used to refine the determined transformer characteristics which may be used to further improve the accuracy of the turns ratio measurement.

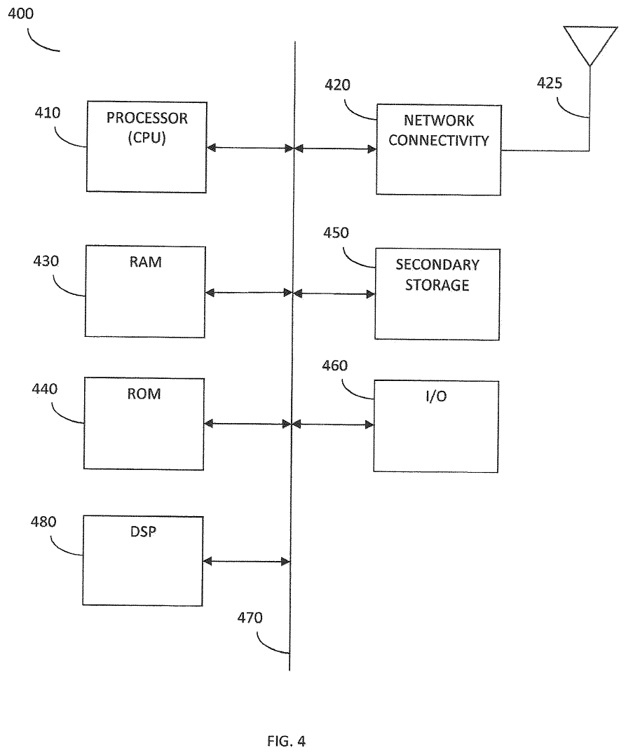

FIG. 4 is a diagram of an embodiment of a system 400 that includes a processor 410 suitable for implementing one or more embodiments disclosed herein, e.g., controller 160 and/or I/O components 170. The processor 410 may control the overall operation of the system.

In addition to the processor 410 (which may be referred to as a central processor unit or CPU), the system 400 might include network connectivity devices 420, random access memory (RAM) 430, read only memory (ROM) 440, secondary storage 450, and input/output (I/O) devices 460. These components might communicate with one another via a bus 470. In some cases, some of these components may not be present or may be combined in various combinations with one another or with other components not shown. These components might be located in a single physical entity or in more than one physical entity. Any actions described herein as being taken by the processor 410 might be taken by the processor 410 alone or by the processor 410 in conjunction with one or more components shown or not shown in the drawing, such as a digital signal processor (DSP) 480. Although the DSP 480 is shown as a separate component, the DSP 480 might be incorporated into the processor 410.

The processor 410 executes instructions, codes, computer programs, or scripts that it might access from the network connectivity devices 420, RAM 430, ROM 440, or secondary storage 450 (which might include various disk-based systems such as hard disk, floppy disk, or optical disk). While only one CPU 410 is shown, multiple processors may be present. Thus, while instructions may be discussed as being executed by a processor, the instructions may be executed simultaneously, serially, or otherwise by one or multiple processors. The processor 410 may be implemented as one or more CPU chips and may be a hardware device capable of executing computer instructions.

The network connectivity devices 420 may take the form of modems, modem banks, Ethernet devices, universal serial bus (USB) interface devices, serial interfaces, token ring devices, fiber distributed data interface (FDDI) devices, wireless local area network (WLAN) devices, radio transceiver devices such as code division multiple access (CDMA) devices, global system for mobile communications (GSM) radio transceiver devices, universal mobile telecommunications system (UMTS) radio transceiver devices, long term evolution (LTE) radio transceiver devices, worldwide interoperability for microwave access (WiMAX) devices, controller area network (CAN), domestic digital bus (D2B), and/or other well-known devices for connecting to networks. These network connectivity devices 420 may enable the processor 410 to communicate with the Internet or one or more telecommunications networks or other networks from which the processor 410 might receive information or to which the processor 410 might output information. The network connectivity devices 420 might also include one or more transceiver components 425 capable of transmitting and/or receiving data wirelessly.

The RAM 430 might be used to store volatile data and perhaps to store instructions that are executed by the processor 410. The ROM 440 is a non-volatile memory device that typically has a smaller memory capacity than the memory capacity of the secondary storage 450. ROM 440 might be used to store instructions and perhaps data that are read during execution of the instructions. Access to both RAM 430 and ROM 440 is typically faster than to secondary storage 450. The secondary storage 450 is typically comprised of one or more disk drives or tape drives and might be used for non-volatile storage of data or as an over-flow data storage device if RAM 430 is not large enough to hold all working data. Secondary storage 450 may be used to store programs that are loaded into RAM 430 when such programs are selected for execution.

The I/O devices 460 may include liquid crystal displays (LCDs), touch screen displays, keyboards, keypads, switches, dials, mice, track balls, voice recognizers, card readers, paper tape readers, printers, video monitors, or other well-known input/output devices. Also, the transceiver components 425 might be considered to be a component of the I/O devices 460 instead of or in addition to being a component of the network connectivity devices 420.

### Transformer Ratio Measurement

Measuring voltage ratio and converting to transformer turns ratio is influenced by practical issues, such as cores whose permeability and loss changes with applied voltage and causes conversion errors. This is especially troublesome when testing three-phase transformers using single-phase excitation. Three-phase transformers typically use cores more efficiently than do single-phase transformers, thus the loss and permeability effects may be reduced, provided three-phase excitation is employed. Some advantages of using three-phase excitation for ratio measurement of three-phase transformers include reduced dependence on test voltage, ability to identify transformer's configuration, ability to measure directly the ratio and phase shift of phase shifting transformers, and ability to provide additional information regarding the balance of the phases, shorted turns, and excessive core loss.

The measurement of turns ratios is used as a tool during manufacturing as well as planned maintenance procedures for identifying problems with power and distribution transformers. Changes in ratios can be indicative of problems within the transformer such as turn-to-turn insulation failure, interwinding insulation failure, or core structure insulation failure. To identify such failures, it is important to measure transformer turns ratios consistently and accurately.

Traditionally, transformer turns ratios were measured using transformer ratio-arm bridges. One such device measures the ratio in the traditional European “Step-Down” connection, another device measures the ratio in the traditional American “Step-Up” connection. These manual instruments use a phase sensitive null detector which allows for an easy way to balance the ratio dials. No phase reading was provided by these original instruments.

Phase readings are also important in identifying problems with transformers, thus subsequent instruments would provide a phase reading. Many current instruments provide a phase as well as ratio reading.

The next step in the evolution of the transformer ratiometer or transformer turns ratiometer is three-phase excitation for the measurement of turns ratios of three-phase transformers. Such instruments provide improved tools for identifying problems on three-phase transformers. These tools are more sensitive, excitation voltage independent, and are not available for single-phase excitation test equipment.

In the following paragraphs, errors of determining turns ratio based on the measurement of voltage ratio are discussed. Such errors may be introduced by the characteristics of the test specimen and by its configuration or connection to the measuring instrument. These errors can be viewed as “systematic errors” and will be present in addition to any errors that the test set itself may introduce.

A basis for transformer turns ratio measurement is the assumption that all of the magnetic flux within the transformer will be linking the windings being measured. Using this assumption, the transformer turns ratio will be equal to the voltage ratio as measured on the windings in question.

As the above assumption is in error due to leakage flux, an approximate turns ratio of a transformer can be determined by exciting the core of the transformer and measuring the voltages of the two windings. Such a measurement will be in error that is inversely proportional to the coupling coefficient between the windings. Also, such a measurement assumes that the windings are not loaded, that is-carry no current.

Practical measuring circuits may require the core to be excited. Such excitation may be provided by applying excitation to any winding on the transformer. The excited winding may be the high voltage winding, in which case the circuit works in a step-down” mode. If the excited winding is the low voltage winding, then the circuit works in the step-up mode. Such practical connections may present loading on the winding. The effect of various connections will be examined below.

### High Voltage Excitation Connection

This is the step-down connection. The excitation is applied to the high voltage (HV) winding and the turns ratio is determined from the voltage ratio as measured on the HV and the low voltage (LV) winding. As the HV winding carries magnetizing current, there may be an error in the measurement. The error is proportional to the excitation current multiplied by the HV winding resistance. The in-phase component of the excitation current may cause a positive ratio error, while the quadrature component may cause a negative phase error. Another important factor is the coupling coefficient. As the coefficient is typically less than 1, it may case a positive ratio error. Also of concern are the eddy currents within the core or shorted turns on the core. These may cause a negative phase error.

### Low Voltage Excitation Connection

This is the step-up connection. The excitation is applied to the LV winding and the turns ratio is determined from the voltage ratio as measured on the HV and the LV winding. As the LV winding carries magnetizing current, there may be an error in the measurement. The error may be proportional to the excitation current multiplied by the LV winding resistance. The in-phase component of the excitation current may cause a negative ratio error, while the quadrature component may cause a negative phase error. Another factor is the coupling coefficient. The coupling coefficient between the HV and LV windings is not the same as between the LV and HV windings. As the coefficient is typically less than 1, it may case a negative ratio error. Also of concern are the eddy currents within the core or shorted turns on the core. These may cause a negative phase error.

### Excitation Voltage and Frequency

Some standards specify the use of a voltage no higher than the rated voltage and a frequency no lower than the rated frequency of the test specimen. Typically, there is no mention in the standards as to the wave shape of the excitation signal. Using a frequency higher than the rated frequency may be advantageous as it typically reduces excitation losses and improves coupling between the windings thus reducing errors. There is also no requirement for limiting the excitation to a sinusoidal voltage, other wave shapes may work equally well, for example, a square-wave. If good accuracy in ratio and phase departure are desired, excitation other than a sine wave may require signal processing in order for the results to be responsive to the fundamental of the excitation voltage. High accuracy turns ratio measurements are improved by tight coupling between windings, and tight coupling depends, in part, on the permeability of the core. As the permeability of the core increases with an increase in excitation voltage, there may be a tendency to use a higher test voltage for determining the turns ratio from the voltage ratio.

### Discussion on Single-Phase Ratio Measurements

As the ratio errors due to excitation and coupling discussed above are positive for HV excitation and negative for LV excitation, there may be cancellation if the HV excited reading was averaged with the LV excited reading. Unfortunately, this cancellation is typically only partially effective. Cancellation is only partial because the HV excitation losses may not be the same as the LV excitation losses. Also, the coefficient of coupling between the HV and the LV winding may not be the same as the coupling between LV and the HV windings. This may be due to the different positioning of the windings with respect to the core. As mentioned above, the voltage ratio errors due to excitation losses may be influenced by the test voltage. For efficient transformers, such as those meeting the department of energy (DOE) standard efficiency levels of 2007, the errors due to excitation losses are estimated at ˜0.005% at rated voltage, increasing to ˜0.02% at 1% of rated voltage, and ˜0.04% at 0.1% of rated voltage.

Another important factor in addition to the influence of excitation losses on turns ratio accuracy is the influence of the coupling coefficient on the accuracy of the voltage ratio measurement. The coupling coefficient depends, at least in part, on the geometry of the windings and the permeability of the core. As the permeability of the core decreases with a reduction in the excitation voltage, so does the coupling coefficient. The coupling coefficient is also smaller for high voltage transformers due in part to providing adequate space for insulation. Measurements have shown that the ratio error for power transformers typically increases by ˜0.03% when testing at 1% of rated voltage, and by ˜0.06% when tested at 0.1% of rated voltage as compared to a test at rated voltage. Combining the two effects that depend on excitation voltage, the ratio error may increase by ˜0.05% when testing at 1% of rated voltage and ˜0.1% when testing at 0.1% of rated voltage. Some transformers are labelled “high impedance”. These are usually high voltage transformers used on power networks to limit short circuit currents. These transformers typically have a lower coefficient of coupling and will exhibit larger ratio error influences due to excitation voltage. The rating of the transformer under test can be used to apply corrections to improve the accuracy of the voltage ratio measurement being converted to the transformer turns ratio.

In addition to the phase error caused by excitation loss, there may be additional phase errors present in the ratio determination. These additional phase errors may be due to the eddy currents within the core. The better the core, the lower the eddy currents, the lower the phase shift. Typically, this phase shift is in the range of 0.03 to 0.10 degrees. The phase shift may also be caused by other eddy currents within the assembly. Being sensitive to shorted turns, grounded core-bolts, and similar, the phase shift is a good indicator of problems within a transformer.

### Single-Phase Measurements of Three-Phase Transformers.

Three-phase power transformers present numerous turns ratio measuring challenges. One such challenge being that there are a variety of transformer configurations, namely wye (Y), wye-neutral (Yn), delta (D), zig-zag (Z), zig-zag-neutral (Zn) and various combinations between them. Not all of these configurations are used on a power system, but the combinations of the above amount to 25 distinct possible configurations. In addition to this, there are the transformers with tertiary windings. Each configuration has an optimal or correct method used to measure their turns ratio.

In some approaches, the turns ratio of all of these transformers were measured using single phase excitation. Some of the configurations can have their turns ratio measured using only one connection, while other configurations can have their turns measured using two different connections. The latter may result in two different answers and presents a problem of deciding which of them is correct. To illustrate the problems of single phase excitation measurements, the measurements of the more popular configurations are analyzed below.

### Yy Transformers

When measuring the ratio of a three-phase transformer, one approach is to pick a connection that energizes one phase of the transformer and then measure the voltage ratio of the turns associated with that phase. For example, on a Ynyn configuration the phase-to-neutral connection of each winding may be measured. Such a connection would provide a ratio for each phase-A, B, and C. There is also the possibility of measuring the ratio using the line-to-line connection of each winding, which would provide a ratio for a combination of phases, namely-AB, BC, CA. The difference in ratio readings between these connections is typically not very large and may be due to the differences in the excitation losses and coupling between all the windings. When connected phase-to-neutral the test set energizes only one leg of the core assembly at 100%, while the other two legs are energized at approximately 50% each. For line-to-line excitation, two of the phases are energized at 100%, with the third phase sitting idle at ˜0%. The voltage ratio measurement using the line-to-line excitation may provide a more accurate representation of the turns ratio and is typically less sensitive to excitation voltage than the line-to-neutral excitation connection.

### Yd Transformers

A Ynd transformer presents a challenge due to the Delta connection which will carry current when the transformer is excited single-phase, be it line-to-neutral or line-to-line. This condition breaks one of the rules for determining the proper turns ratio by measuring the voltage ratio, the winding is loaded. Examining the line-to-neutral excitation situation, the single excited winding within the delta is supplying excitation to the other two windings. The situation is different with line-to-line excitation, where two of the delta windings are supplying excitation to the third winding. As there is current circulating within the delta, this causes loading and therefore errors due to loading. The loading with the line-to-line excitation is considerably less than the loading with line-to-neutral excitation, thus the line-to-line excitation provides a more accurate voltage ratio reading. The loading on the delta winding make the connections more sensitive to excitation voltage, with the line-to-neutral excitation being considerably more sensitive.

The alternative to dealing with the “loaded delta” connection, would be to test the transformer using the step-up connection, namely treat the Yd transformer as a Dy transformer. As explained herein, this connection does not load the delta, thus its accuracy is not influenced as much by the excitation voltage.

Thus, when testing a Yd transformer, one approach is to test it as a Dy transformer in the step-up connection for accurate voltage ratio measurement. Alternatively, the line-to-line excitation, with a line-to-line short, of the transformer may be used. The line-to-neutral excitation may not be used as it loads the delta winding, and as a result is excitation voltage dependent.

### Yz Transformers

In testing a Ynzn, Yzn transformer, the problem of turns ratio measurement is similar to that of the Ynd connection. As each phase of the Z winding consists of components from two phases, line-to-neutral excitation may not be used to test ratio. However, line-to-line excitation may be used. Thus, exciting the transformer line-to-line, automatically excites two phases similarly to that of a Yy transformer. The voltage ratio in this connection is an accurate measure of the turns ratio, very similar to the voltage ratio of a Yy transformer connected line-to-line.

During manufacturing each of the windings of a Z connection may be measured separately. This can be accomplished by using the line-to-neutral connection, or the line-to-line connection with a line-to-line short. Similarly to other connections, the line-to-line connection excites two limbs of the transformer under test and is much less voltage dependent.

### Dy and Dz Transformers

Measuring turns ratio on Delta high voltage transformers, be they Dy, Dyn, or Dzn, typically presents one choice when exciting the transformer, that is line-to-line excitation with line-to-line shorting. The shorting can be also applied on the secondary side, but this presents a load on the measured winding, thus affecting the accuracy of the measurement. It should be noted that with the delta being on the high side, and using the step-down connection, the delta is not loaded and improved accuracy between the voltage ratio and the turns ratio can be obtained.

### Tertiary Delta Windings

A primary function of the tertiary delta winding is to improve the symmetry of the three-phase system, in particular to reduce the amount of negative sequence component. The negative sequence component is typically caused by single-phase loads and unequal impedances of line conductors. In some approaches, all transmission lines are transposed so that all line conductors will have the same impedance, resulting in little or no negative sequence component being generated.

However, tertiary delta windings are of reduced capacity, typically 20-30% of the transformer. When testing the Yd ratio on a typical Ynynd transformer, the tertiary acts like a normal delta connection. The tertiary is thus loaded and being under-powered (presenting a higher impedance), causes larger errors. A measurement of the Yd ratio on a tertiary winding, with a 20% rating, may have a five times larger test voltage influence than the influence on a regular Yd transformer. Therefore, such tertiary windings may be tested using three-phase or line-to-line excitation as this connection presents the least loading on the delta. The turns ratio may be measured using the step-up configuration, which presents no loading on the delta winding.

A problem with ratio testing of tertiary delta windings may crop up when the delta is loaded with another transformer (typically Zy) to provide station service load. When internally connected to the delta winding, the service transformer draws excitation current from the delta winding when the HV winding is excited for ratio measurement. This may cause excessive measurement errors. In this case, ratio measurement may excite the delta for the Yd ratio measurement in the step-up configuration and at the same time the Zy ratio in the step-down configuration.

Table 1 presents approximate values of ratio errors as a function of test voltage for different connections of three-phase transformers. Reduction in voltage influence for transformers excited two-phase and three-phase may be realized.

TABLE 1
Ratio error (%) as a function of excitation voltage

| V (%) | 1Φ-1Φ | 3Φ-3Φ | 2Φ-3Φ | 1Φ-3Φ | 3Φ-D | 2Φ-D | 1Φ-D |
|---|---|---|---|---|---|---|---|
| 100 | 0.006 | 0.004 | 0.005 | 0.01 | 0.01 | 0.02-0.03 | 0.04-0.06 |
| 10 | 0.012 | 0.008 | 0.01 | 0.02 | 0.02 | 0.04-0.06 | 0.08-0.12 |
| 1 | 0.024 | 0.016 | 0.02 | 0.04 | 0.04 | 0.08-0.12 | 0.16-0.24 |
| 0.1 | 0.048 | 0.032 | 0.04 | 0.08 | 0.08 | 0.16-0.24 | 0.32-0.48 |
| 0.01 | 0.096 | 0.064 | 0.08 | 0.16 | 0.16 | 0.32-0.48 | 0.64-0.96 |
| 0.001 | 0.192 | 0.128 | 0.16 | 0.32 | 0.32 | 0.64-0.48 | 1.28-1.92 |

Table 1 was assembled from measurements using different instruments operating at different voltages and measuring a variety of transformers. In table 1, V (%)=Excitation voltage in % of rated voltage; 1ϕ-1ϕ=Single-phase excitation of a single-phase transformer; 3ϕ-3ϕ=Three-phase excitation of a three-phase transformer; 2ϕ-3ϕ=Two-phase excitation of a three-phase transformer; 10-3ϕ=Single-phase excitation of a three-phase transformer; 3ϕ-D=Three-phase excitation of a three-phase transformer with a tertiary delta; 2ϕ-D=Two-phase excitation of a three-phase transformer with a tertiary delta; and 1ϕ-D=Single-phase excitation of a three-phase transformer with a tertiary delta.

Single-Phase Measurements of Three-Phase transformers

Accuracy of turns ratio determination based on voltage ratio measurements may be subject to influences and connections as discussed above. Based on this information, a table of voltage influences on different connections may be provided, e.g., table 1. Thus, a connection for the most accurate measurement may be selected. Improved accuracy of turns ratio determination based on the voltage ratio measurement may be achieved based on the following conditions: excite test specimen three-phase or line-to-line; if required, apply shorts on the excited winding; and measure transformers with delta connected secondary windings in the step-up configuration. The foregoing list of conditions is not meant to be exhaustive and other conditions may contribute to improved accuracy of turns ratio determination.

### Three-Phase Testing

In single-phase testing of three-phase transformers, different connections may provide voltage ratios that are very close to the turns ratios, some with larger errors and some with smaller errors. Voltage ratio measurements which excite only one phase of a three-phase transformer are typically subject to larger errors and are more sensitive to excitation voltage than a voltage ratio measurement that excites two phases of the transformer. Thus, a voltage ratio measurement that excites all three-phases may provide even more accurate turns ratio based on the voltage ratio and such a measurement may have the smallest excitation voltage influence of the three options (single-phase, two-phase, or three-phase excitation).

In the case of single phase excitation, the one excited phase has to supply the excitation losses for the whole core, while in the case of two-phase excitation, the loss is shared by the two phases. The situation may be further improved with three-phase excitation, where each phase supplies its share of the excitation loss. Further, in three-phase excitation the voltage ratio depends not only on the excitation and coupling between the windings of one phase, but also on the excitation and coupling between all of the windings on all of the phases of the transformer.

A three-phase, three-wire, excitation system combined with a multi-channel measuring system that is capable of measuring line-to-line and line-to-neutral voltages may be used as a three-phase transformer ratiometer. Such a system can excite Delta, Wye, or Zig-zag transformers and measure voltages and determine their phase positions with high accuracy. Thus, the instrument may identify any of the many three-phase connections used on three-phase power transformers. Further, such a system may perform any of the appropriate single-phase measurements while being excited three-phase. The system, therefore, not only determines the ratios of the various phases, but also provides a very accurate on-line comparison between the various phases. Measurements on a variety of transformer configurations, and sizes, indicated that the measurements are not only accurate, but also less sensitive to excitation voltage than any single-phase excitation connections of a three-phase transformer. In addition to all of the above, the three-phase measurement system is ideal for measuring the ratio and phase shift of phase-shifting transformers or of transformers with variable phase shifts. The precise ratios and phase shifts are measured quickly and directly.

### Symmetrical Components

A three-phase measurement system is capable of providing additional information pertaining to the health and operation of the transformer under test. Whereas the single-phase excitation tests would provide three ratios and three phase angle errors, the three-phase system, in addition to three ratios and phase angle errors, provides three primary voltages associated with their phase angles, as well as three secondary voltages associated with their phase angles. This information allows determination of the symmetrical components of the transformer's excitation voltage as well as that of the transformer's response.

Once symmetrical components are determined, the “ratio of the transformer” is calculated from the ratio of the positive (+) sequence components and the phase error is determined from the difference between the phases of the positive (+) sequence components. Continuing, with the transformer being a linear device, it should transform voltage and current linearly according to the laws of physics. As these laws apply equally to the symmetrical components, a comparison of the symmetrical components on the secondary side with the components on the primary side provides valuable information as to the proper functioning of the transformer. Analysis of three-phase transformers shows that an incorrect number of turns on any of the windings (incorrect turns ratio) or excessive core loss on one of the phases will result in symmetrical distortion, generation negative (−) sequence on the secondary winding. The generation of negative sequence is more sensitive and accurate to ratio unbalances than the comparison of individual ratios and phase errors. This provides the tester with additional valuable information that pertains to the health of the transformer.

### Three-Phase Accuracy Improvements

Three-phase excitation provides designed core excitation for proper operation of the transformer and thus is more suitable for test applications. As accurate ratio measurements depend not only on the excitation of the phase being tested, but also on the coupling between all of the windings on a transformer assembly, three-phase excitation provides the same inter-winding coupling during ratio measurements as would be encountered during service conditions.

Three-phase excitation can be used to excite the hi-side windings of the transformer for step-down measurements, or to excite the lo-side windings for the step-up measurements. In either case, the measurements may provide the three-phase ratio and phase shift; per-phase ratio and phase shift; and degree of negative sequence distortion. Three-phase measurements provide improved information that relates to the health of the transformer relative to single-phase ratio measurements conducted using single-phase excitation.

As for single-phase ratio measurements using single-phase excitation, such measurements may be conducted using the line-to-line connection which excites two phases. Single-phase ratio measurements using the line-to-neutral connection, which excites only one phase, may be used with the caveat that these measurements are test voltage dependent. Single-phase ratio measurements using the line-to-neutral connection, which excite only one phase, with a delta secondary test winding are test voltage dependent as the delta winding is loaded and no longer qualifies for ratio measurements.

Embodiments described herein may include any combination of the following features: uses “reversible DC” (square-wave) excitation over a range of 1-48 volts; capable of exciting the sample at power line frequency, its harmonics or its sub-harmonics; provides single-phase excitation for single-phase or three-phase test samples; provides measurements of voltage, current, active power and reactive power of single-phase excitation; the instrument can conduct tests on three-phase transformers by applying single-phase excitation, phase-by-phase, to one set of windings and measuring the resulting voltages in the other set of windings; provides three-phase excitation for three-phase test samples; the three-phase source being very highly symmetrical; provides measurements of voltages, phase angles, currents, active powers and reactive powers for each phase of the three-phase excitation; measures the test sample with excitation applied to the HV winding or to the LV windings; measurements are conducted truly differentially, thus allowing interconnections between the test windings or grounds on the windings; the instrument is capable of applying corrections to the measured voltage ratio so that the results become very close to the true turns ratio of the transformer; as one error in ratio determination is due to excitation losses, it measures the transformer characteristics at two or more excitation voltages and determines the correction to the voltage ratio to become true turns ratio; another method of determining the true turns ratio is to average two measurements, one measured with the HV winding excited and the other measured with the LV winding excited at the same flux level the instrument calculates the symmetrical components in the excitation signal applied to one winding as well as that of the other winding of the transformer; comparing the applied positive sequence voltage to one winding with the positive sequence voltage on the other winding the instrument determines the true three-phase ratio, as well as any phase displacement; the instrument can determine problems within the test transformer by comparing the applied negative sequence to one winding with the negative sequence measured on the other winding of the transformer.

Regarding the aforementioned features, three-phase excitation of a three-phase transformer allows computation of the positive and negative sequence of the excitation signal as well as that of the other winding. The ratio of the positive sequence components provides a true three-phase turns ratio, and the difference in phase value provides the true three-phase phase shift of the transformer. In a well-balanced three-phase system, the positive sequence is very close to the average of the three line-to-line voltages. The negative sequence is approximately the average of the differences between three line-to-line voltages. The above expression is only ‘approximate’ as differences in phase angles as well magnitude need to be accounted for. The true three phase turns ratio is very close to the average of the three per-phase turns ratios. The true three-phase phase shift is approximately the average of the three per-phase phase shifts. An ideal three-phase transformer will provide no distortion, no distortion with respect to frequency (that is—not generate any harmonics) as well as no distortion with respect to “sequence”, that is—not generating any negative sequence components. Generation of negative sequence components is a sign of differences between the individual phases which includes such things as different turn ratios or different core characteristics (core loss). Different turn ratios or different core losses indicate shorted turns or similar problems in the transformer.

In embodiments described herein, test excitation features may include any combination of the following features: instrument shall provide low voltage based three phase excitation (1 to 48V switched DC); instrument shall provide low voltage based single phase excitation (1 to 48V switched DC); instrument shall provide ability to inject low voltage excitation test voltage into the primary windings of the transformer; instrument shall provide ability to inject low voltage excitation test voltage into the secondary windings of the transformer; the secondary winding voltage injection provides a unique method to generate high voltage primary winding injection; instrument shall provide automatic and/or manual switching of transformer primary versus secondary low voltage injection (as determined by customer preference and/or transformer design/construction); internal instrument test voltage selection (between primary and secondary side of transformer) removes the need to externally switch test Lead connections at the transformer-safer and more efficient (saving overall test completion time); the instrument shall have the capability to generate variable frequency low voltage injection, providing a means to measure multiple voltage ratios, excitation currents, and phase variations to produce a transformer core loss characterization curve which can be used to apply ratio correction algorithms; variable frequency, low voltage injection applied to simulate lower test voltage as a means to excite within the linear portion of the transformer under test—this is specifically relevant to testing current transformers (CTs); the instrument shall have the capability to generate variable low voltage injections, providing a means to measure multiple voltage ratios, excitation currents, and phase variations to produce a transformer core loss characterization curve which can be used to apply ratio correction algorithms

In embodiments described herein, test measurement features may include any combination of the following features: instrument shall have the capability to measure voltage ratios of all three phases simultaneously for three phase transformers; instrument shall have the capability to measure phase shift and phase deviation (primary versus secondary) of all three phases simultaneously for three phase transformers; instrument shall have the capability to measure excitation current on three phases simultaneously for three phase transformers; instrument shall have the capability to measure voltage ratios on a single phase transformer (phase to phase and/or phase to neutral) as well as any individual phases for three phase transformers (phase to phase and phase to neutral); instrument shall have the capability to measure excitation current for single phase transformers; instrument shall provide a smart excitation measurement method preventing excitation and/or measurement circuit damage due to incorrect test lead connections; instrument shall provide a smart excitation measurement method preventing instrument damage and limiting user danger due to transformer step-up overvoltage conditions created by high winding ratio transformers which exceed a set design limit; instrument shall provide a smart excitation measurement method to manage automatic and manual switching of primary/secondary excitation based on determination of the winding turns ratio of the transformer under test; instrument shall provide an automatic measurement control methodology for the execution of multiple excitation voltage measurements providing a characterization of the core of the transformer under test; the instrument shall apply turns ratio correction algorithms to improve the reported turns ratio using the determined transformer core characterization obtained in steps above; instrument shall improve overall test time efficiency on multi-tap transformers by applying initial determined transformer core characteristics and resulting correction algorithm to recurring turns ratio tests.

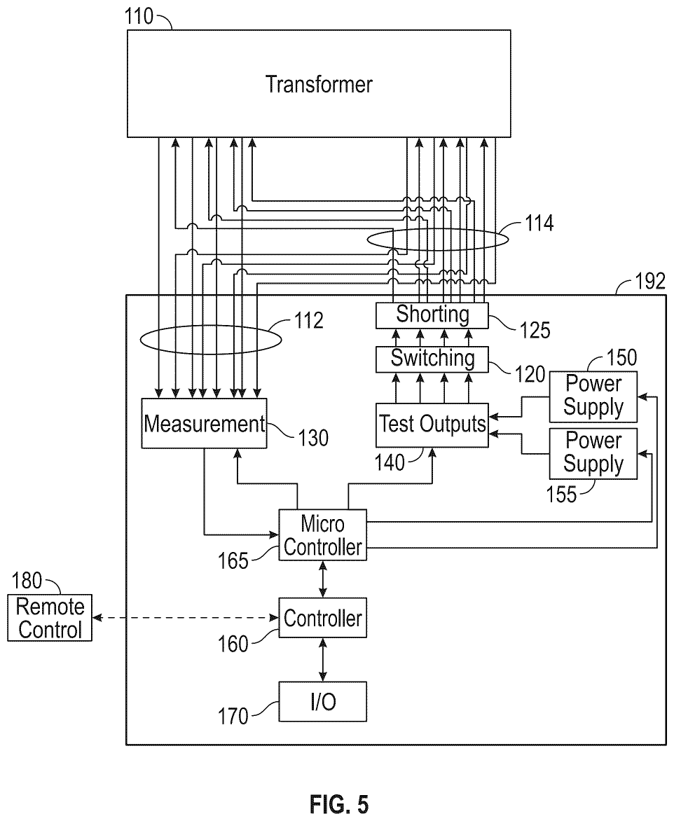

Turning now to FIG. 5, a transformer tester 192 is described. Some components of the transformer tester 192 are common or similar to like components in the turns ratio meter 190 described above. In an embodiment, the transformer tester 192 incorporates apparatus and instructions, software, and/or firmware executable by the micro controller 165 and/or by the controller 160 to perform transformer turns ratio determination. At the same time, and as described more fully below, the transformer tester 192 is configured to perform additional transformer tests including determining transformer windings resistance values, a short-circuit impedance of the transformer, transformer eddy current losses, transformer hysteresis losses, and transformer symmetrical components. It will be appreciated that incorporating multiple testing capabilities in a single device can provide advantages to field technicians and/or original equipment manufacturer quality control technicians. Leads connecting the transformer tester 192 and the transformer 110 (e.g., a transformer under test) need only be completed once and multiple different tests can be completed. Incorporating multiple testing capabilities in a single device reduces the number of devices that a technician needs to learn how to operate and/or needs to carry to the proximity of the transformer under test. Notwithstanding, the transformer tester 192 can also be used to run a single transformer test in isolation, without completing the other tests the device is capable of executing.

In an embodiment, the transformer tester 192 comprises the measurement connections 112, the test output connections 114, the switching matrix 120, a measurement circuit 130, a test output circuit 140, a first power supply 150, a controller 160, a microcontroller 165, an I/O component 170, and an optional remote control 180. The measurement connections 112 may be referred to as measurement leads; the test output connections 114 may also be referred to as test output leads. The connections 112, 114 can be collectively referred to as test leads in some contexts. The components 112, 114, 120, 130, 140, 150, 160, 165, 170, and optional component 180 are substantially similar to the like components described above with reference to the turns ratio meter 190, albeit they may be used for testing other than just transformer turns ratio determination. Additionally, the controller 160 and microcontroller 165 are different from these components described with reference to the turns ratio meter 190 in that, while they also contain instructions and/or software and/or firmware to determine transformer turns ratio, they further contain additional instructions and/or software and/or firmware for performing testing procedures that the turns ratio meter 190 was not configured to perform.

In an embodiment, the transformer tester 192 further comprises a shorting circuit 125 and a second power supply 155. The shorting circuit comprises high capacity field effect transistors (FETs) that can be controlled by the microcontroller 165 or the controller 160 to act as switches or as solid-state relays (SSRs) such that in a first state an FET provides an open circuit path (no current can flow through the FET) and in a second state the FET provides a closed-circuit path (current can flow through the FET). In an embodiment, the FETs are configured to be connected to test output connections 114 in such a way as to provide a short across the leads of one or more windings of the transformer 110. In an embodiment, the power supply 150 may provide a first DC voltage power output and the second power supply 155 may provide a second DC voltage power output at a different voltage level.

As illustrated in FIG. 5, the measurement connections 112 and the test output connections 114 promote testing a three-phase transformer without having to disconnect and reconnect test leads. Additionally, the measurement connections 112 and the test output connections 114 promote testing two or more phases of the transformer 110 at the same time.

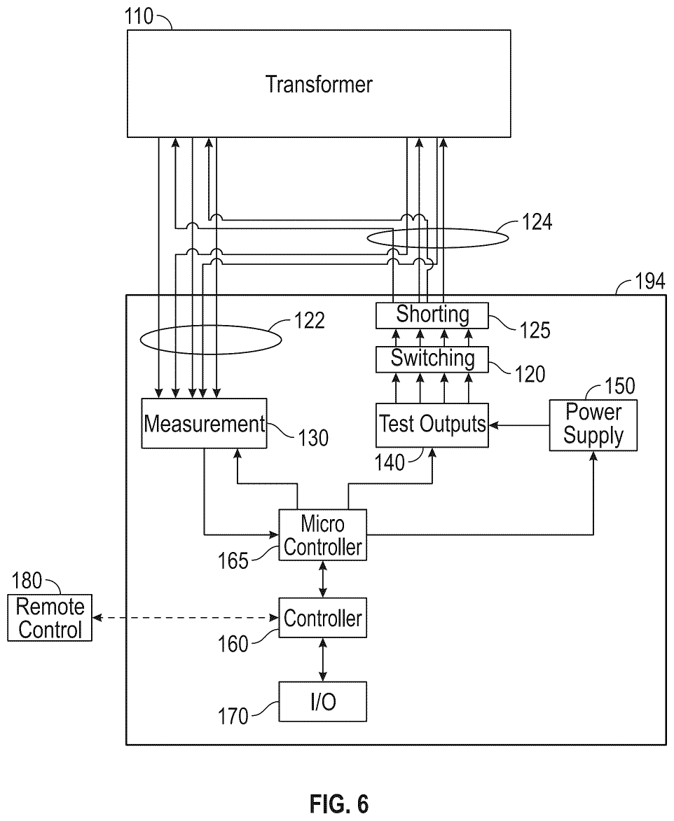

Turning now to FIG. 6, an alternative transformer tester 194 is described. The alternative transformer tester 194 is substantially similar to the transformer tester 192, with the difference that the alternative transformer tester 194 comprises four measurement connections 122 and four test output connections 124, whereas the measurement connections 112 featured eight connections and the test output connections 114 featured eight connections. The alternative transformer tester 194 is intended for use in testing single-phase transformers or in testing multiple phase transformers, one phase at a time. The alternative transformer tester 194, however, is otherwise configured to perform the same kinds of tests as the transformer tester 192, e.g., determining the transformer turns ratio, transformer windings resistance values, the short-circuit impedance of the transformer, the transformer stray losses, the transformer eddy current losses, and the transformer symmetrical components.

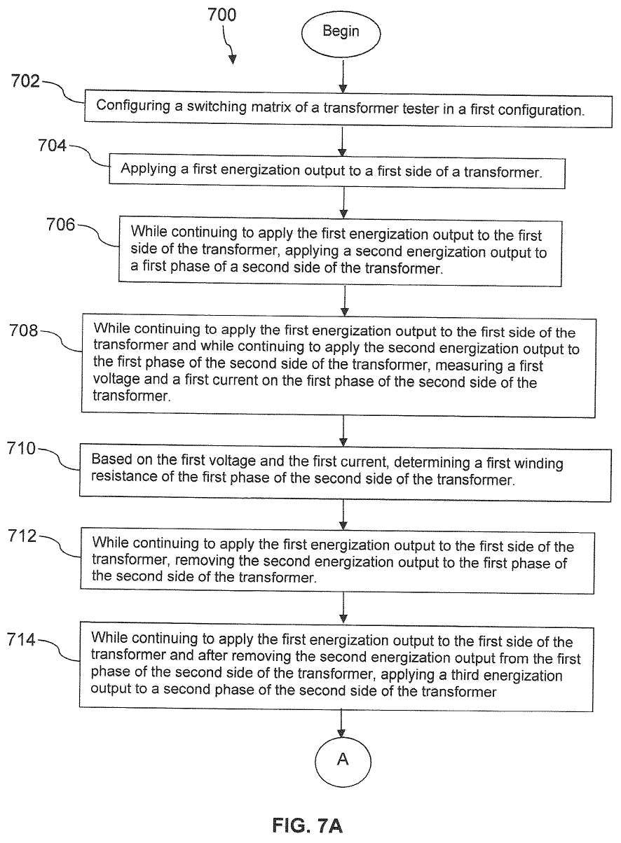

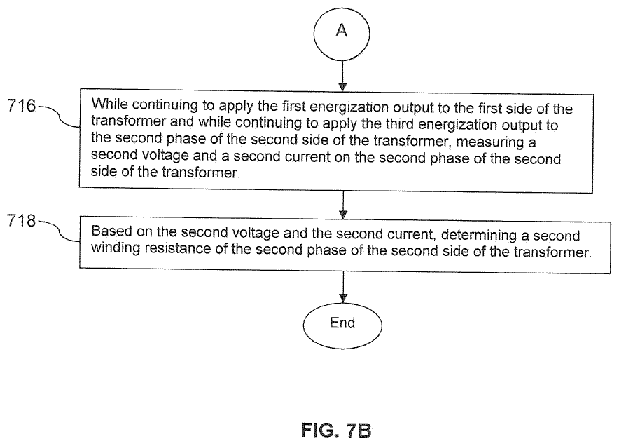

Turning now to FIG. 7A and FIG. 7B, a method 700 is described. In an embodiment, the method 700 is a method of measuring winding resistance of a transformer. In an embodiment, the method 700 may be performed by the transformer tester 192. In an embodiment, the method 700 supports energizing a first side of the transformer 110 and then (a) measuring a resistance of a phase-1 winding of a second side of the transformer 110, (b) measuring a resistance of a phase-2 winding of the second side of the transformer 110, and (c) measuring a resistance of a phase-3 winding of the second side of the transformer 110. The measurements (a), (b), and (c) can be done while keeping the first side of the transformer 110 energized, thus saving much time in charging and discharging the core of the transformer 110 between measurements (a), (b), and (c) as winding resistance testing would be conventionally performed. This is advantageous when completing winding resistance tests while the transformer core remains hot, for example during what may be referred to as a “heat run test.” In this scenario, it is desired to complete winding resistance measurements within 10 minutes.

Once the resistance of the phase-1, phase-2, and phase-3 windings of the second side of the transformer have been determined in this way, the configuration can be flipped, and the second side of the transformer 110 can be energized and held energized while then (d) measuring a resistance in a phase-1 winding of the first side of the transformer 110, (e) measuring a resistance in a phase-2 winding of the first side of the transformer 110, and (f) measuring a resistance in a phase-3 winding of the first side of the transformer 110. The old method of testing would have entailed six core charging cycles and five core discharging cycles to capture the winding resistance measurements (a sixth core discharge cycle could be completed AFTER the last winding resistance measurement had been completed, and hence not subject to a timing constraint). The new method of transformer windings resistance testing disclosed herein that is supported by the transformer tester 192 entails only two core charging cycles and one core discharging cycle to capture the winding resistance measurements (a second core discharge cycle could be completed AFTER the last winding resistance measurement had been completed, and hence not subject to a timing constraint). Thus, this novel method entails four fewer core charging cycles and four fewer core discharging cycles within a time constraint to complete a “heat run test.”

At block 702, the method 700 comprises configuring the switching matrix in a first configuration. Configuring the switching matrix 120, for example, may route energization outputs from the test output circuit 140 to the desirable output connections 114 or leads to perform testing on the transformer 110. At block 704, the method 700 comprises applying a first energization output to a first side of a transformer, for example applying a first energization output to a first side of the transformer 110. In an embodiment, the energization output may be applied to a single phase of the first side of the transformer, to two phases of the first side of the transformer concurrently, or to three phases of the first side of the transformer concurrently. In an embodiment, the energization output is a DC voltage. In an embodiment, the energization output is in the range 40 VDC to 200 VDC. In an embodiment, the energization output is in the range 50 VDC to 150 VDC. In an embodiment, the energization output is in the range 75 VDC to 125 VDC. In an embodiment, the energization output is in the range 90 VDC to 110 VDC. In an embodiment, the energization output is in the range 95 VDC to 105 VDC. In an embodiment, the energization output may be an about 100 VDC energization output. In an embodiment, the energization output may be provided by the second power supply 155.

At block 706, the method 700 comprises, while continuing to apply the first energization output to the first side of the transformer, applying a second energization output to a first phase of a second side of the transformer. At block 708, the method 700 comprises, while continuing to apply the first energization output to the first side of the transformer and while continuing to apply the second energization output to the first phase of the second side of the transformer, measuring a first voltage and a first current on the first phase of the second side of the transformer.

At block 710, the method 700 comprises, based on the first voltage and the first current, determining a first winding resistance of the first phase of the second side of the transformer. In an embodiment, the processing of block 710 can be done later, for example at the end of method 700. At block 712, the method 700 comprises, while continuing to apply the first energization output to the first side of the transformer, removing the second energization output from the first phase of the second side of the transformer.

At block 714, the method 700 comprises, while continuing to apply the first energization output to the first side of the transformer and after removing the second energization output from the first phase of the second side of the transformer, applying a third energization output to a second phase of the second side of the transformer. At block 716, the method 700 comprises, while continuing to apply the first energization output to the first side of the transformer and continuing to apply the third energization output to the second phase of the second side of the transformer, measuring a second voltage and a second current on the second phase of the second side of the transformer. At block 718, the method 700 comprises, based on the second voltage and the second current, determining a second winding resistance of the second phase of the second side of the transformer.

In an embodiment, the method 700 may continue in like manner by removing the third energization output from the second phase of the second side of the transformer and by applying a fourth energization output to a third phase of the second side of the transformer, while maintaining the first side of the transformer energized, and measuring a third winding resistance of the third phase of the second side of the transformer.

Then the method 700 may remove the first energization output from the first side of the transformer. These method steps may then be applied in a reverse sense to measure winding resistances of the first phase, the second phase, and the third phase of the first side of the transformer. For example, the switching matrix may be configured in a second configuration, a fifth energization output may be applied to the second side of the transformer to charge the core of the transformer 110. Then, while maintaining this fifth energization output on the second side of the transformer, a sixth energization output may be applied to a first phase of the first side of the transformer, a voltage and current in the first phase of the first side of the transformer can be measured, and a winding resistance of the first phase of first side of the transformer can be determined based on the voltage and current in the first phase of the first side of the transformer. Then the sixth energization output can be removed. While continuing to apply the fifth energization output to the second side of the transformer, a seventh energization output can be applied to a second phase of the first side of the transformer, a voltage and current in the second phase of the first side of the transformer can be measured, and a winding resistance of the second phase of the first side of the transformer can be determined based on this voltage and current. The seventh energization output can be removed from the second phase of the first side of the transformer. While continuing to apply the fifth energization output to the second side of the transformer, an eighth energization output can be applied to a third phase of the first side of the transformer, a voltage and current in the third phase of the first side of the transformer can be measured, and a winding resistance of the third phase of the first side of the transformer can be determined based on this voltage and current. The eighth energization output can be removed from the third phase of the first side of the transformer and the fifth excitation signal can be removed from the second side of the transformer. In an embodiment, the switching matrix may be configured in a different configuration for measuring each of the winding resistances of the second side of the transformer and for measuring each of the winding resistances of the first side of the transformer. It is understood that, in an embodiment, all of the measurements and testing results can be stored as the testing procedure is performed and the determination of winding resistances can be performed as the final step of the test, for example after all energization outputs have been removed from the transformer 110.

In an embodiment, the method 700 further comprises while continuing to apply the first energization output to the first side of the transformer and after removing the second energization output from the first phase of the second side of the transformer, applying a ninth energization output to a third phase of the second side of the transformer; while continuing to apply the first energization output to the first side of the transformer, continuing to apply the third energization output to the second phase of the second side of the transformer, and continuing to apply the ninth energization output to the third phase of the second side of the transformer, measuring a seventh voltage and a seventh current on the third phase of the second side of the transformer, and based on the seventh voltage and the seventh current, determining a third winding resistance of the third phase of the second side of the transformer

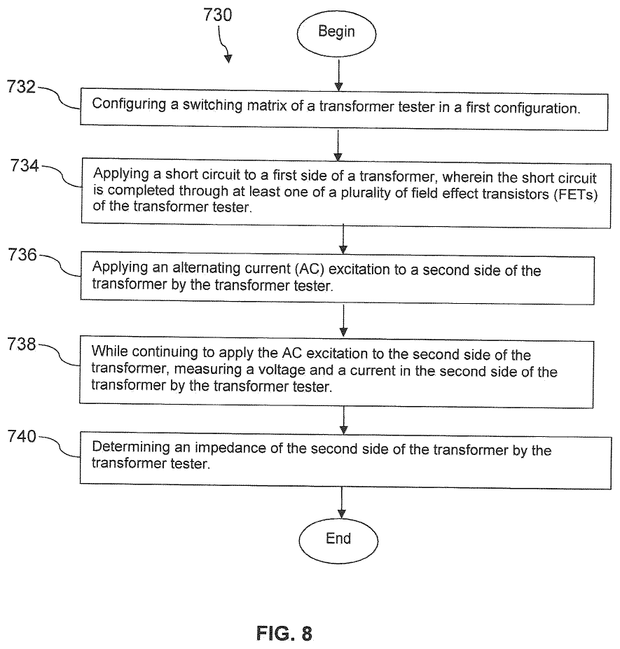

Turning now to FIG. 8, a method 730 for determining short-circuit impedance of the transformer is described. In an embodiment, the method 730 may be performed by the transformer tester 192 or by the alternative transformer tester 194. At block 732, the method 730 comprises configuring a switching matrix of a transformer tester in a first configuration. Configuring the switching matrix 120, for example, may route excitation outputs from the test output circuit 140 to the desirable output connections 114 or leads to perform testing on the transformer 110.

At block 734, the method 730 comprises applying a short circuit to a first side of a transformer (e.g., to a first phase of the first side of the transformer), wherein the short circuit is completed through at least one of a plurality of field effect transistors (FETs) of the transformer tester. In an embodiment, before block 732 and block 734, the method 730 comprises determining (A) virtual inductances and/or impedances of the test output connections 114 (e.g., test output leads) to the transformer 110 and (B) virtual inductances and/or impedances of the short-circuits of the shorting circuit 125. In an embodiment, at block 734, short-circuits are applied to two phases of the first side of the transformer concurrently. In an embodiment, at block 734, short-circuits are applied to three phases of the first side of the transformer concurrently.

At block 736, the method 730 comprises applying an alternating current (AC) excitation to a second side of the transformer (e.g., to a first phase of the second side of the transformer) by the transformer tester. At block 738, while continuing to apply the AC excitation to the second side of the transformer, measuring a voltage and a current in the second side of the transformer by the transformer tester. At block 740, determining a short-circuit impedance of the transformer by the transformer tester based on the voltage and current in the second side of the transformer. In an embodiment, measuring the voltage and current in the second side of the transformer at block 738 comprises measuring a phase angle between the voltage and the current in the second side of the transformer, and determining the short-circuit impedance of the transformer at block 740 is based on the voltage, based on the current, and further based on the phase angle between the voltage and the current in the second side of the transformer. In an embodiment, the short circuit is applied to a first phase of the first side of the transformer and the AC excitation signal is applied to a first phase of the second side of the transformer and wherein determining the impedance of the second side of the transformer based on the voltage and the current determines an impedance of the first phase of the transformer.

In an embodiment, determining the short-circuit impedance of the transformer is further based on (A) a virtual inductance of the test output connections 114 (e.g., test output leads) and (B) a virtual inductance of the short-circuits of the shorting circuit 125. For example, the method 730 may further comprise determining a virtual inductance of a set of leads extending from the transformer windings impedance meter to the first side of the transformer, wherein determining the impedance of the second side of the transformer is further based the virtual inductance of the set of leads extending from the transformer windings impedance meter to the first side of the transformer. In an embodiment, the method 730 may further comprise determining losses in the set of leads extending from the transformer windings impedance meter to the first side of the transformer based on a voltage in the leads extending from the transformer windings impedance meter to the first side of the transformer, based on a current in the leads extending from the transformer windings impedance meter to the first side of the transformer, and based on a phase angle between the current in the leads and the voltage in the leads; determining transformer excitation losses based on a product of a voltage of the AC excitation and the current of the AC excitation and a phase angle of the current of the AC excitation relative to the voltage of the AC excitation; and determining active losses of the transformer by subtracting the losses in the set of leads extending from the transformer windings impedance meter to the first side of the transformer from the transformer excitation losses.

In an embodiment, applying the AC excitation to the second side of the transformer in block 736 comprises increasing the voltage of the AC excitation applied to the second side of the transformer until a rated current is produced in the first side of the transformer. The current in the first side of the transformer may not actually be measured but instead may be calculated based on a known turns ratio of the transformer and based on a measured current in the second side of the transformer. In an embodiment, determining the impedance of the transformer is further based on the turns ratio of the transformer. The turns ratio of the transformer 110 may be input by a user of the transformer tester 192, 194 via the I/O component 170. Alternatively, a user of the transformer tester 192, 194 may input transformer nameplate electrical information including a primary winding voltage rating, a secondary winding voltage rating, and/or a transformer power rating, and the controller 160 may infer the transformer turns ratio from the nameplate electrical information. Alternatively, in an embodiment, the transformer tester 192, 194 may incorporate a transformer turns ratio meter and may determine the turns ratio of the transformer 110 autonomously.

The impedance of the transformer is then determined as a percentage of the voltage of the AC excitation on the second side of the transformer that produces full rated current in the first side of the transformer divided by the full rated voltage of the second side of the transformer. Thus, if the transformer 110 is a 4160/230 volt transformer with 5.78% impedance, it means that it would take 5.78% of rated voltage to produce full rated current in the shorted winding. If the primary is energized, it would take 240 V on the 4160 V primary winding to produce 100% of rated current on the secondary winding. If the secondary is energized it would take 13.29 V on the 230 V secondary winding to produce full rated current in the primary winding. The impedance of a transformer is the same whether the testing involves exciting the second side of the transformer and short-circuiting the first side of the transformer or the testing involves exciting the first side of the transformer and short-circuiting the second side of the transformer.

The method 730 can also be used to determine excitation losses in the transformer 110. A first power delivered to the transformer 110 can be determined by calculating the product of the voltage output by the test output circuit 140 to the second side of the transformer and the in-phase component of the current output by the test output circuit 140 to second side of the transformer. A second power delivered to the first side of the transformer 110 can be determined in a like way by measuring the voltage and current across the first side of the transformer 110. The second power delivered represents losses in the leads and the shorting circuit 125. By subtracting the second power from the first power, the excitation losses in the transformer 110 can be determined.

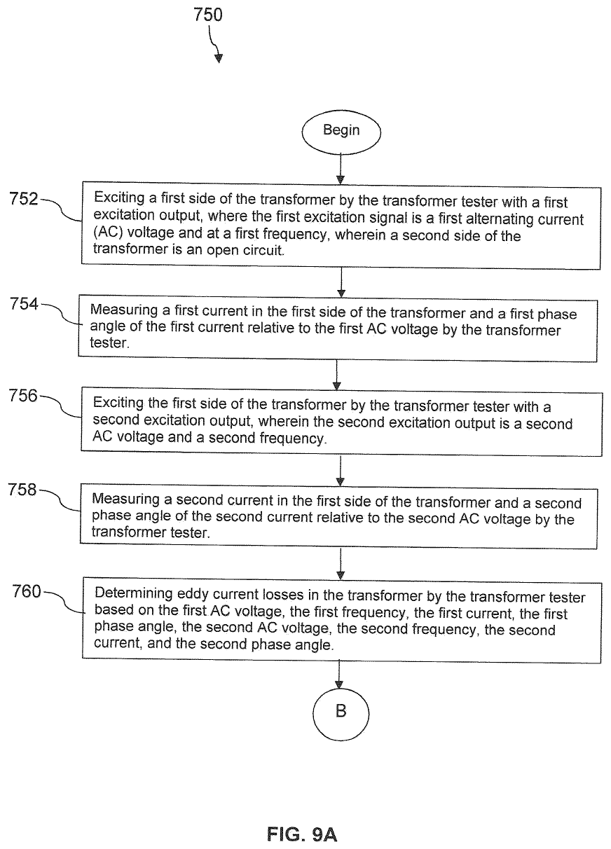

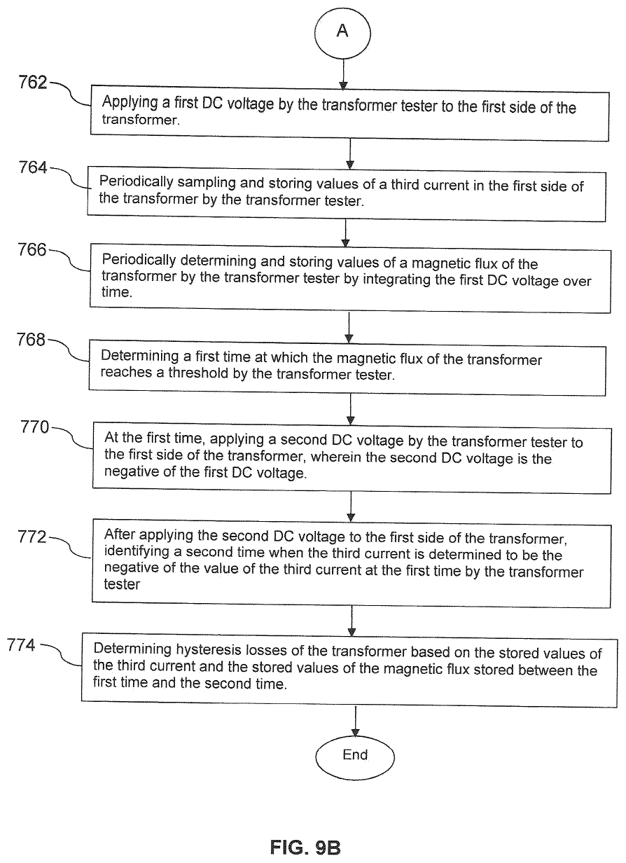

Turning now to FIG. 9A and FIG. 9B, a method 750 is described. In an embodiment, the method 750 is a method for measuring no-load losses in a transformer. At block 752, the method 750 comprises exciting a first side of the transformer by a transformer tester with a first excitation output, where the first excitation output is a first alternating current (AC) voltage and at a first frequency, wherein a second side of the transformer is open. In an embodiment, the method 750 may be performed by the transformer tester 192, 194 described above. In an embodiment, the output connections 114 may not be connected to the second side of the transformer. Alternatively, in an embodiment, the output connections 114 may be connected to the second side of the transformer but the FETs in the shorting circuit may leave these connections to the second side of the transformer open. In an embodiment, the method 740 may comprise configuring the switching matrix to route outputs from the test output circuit 140 to the transformer.

At block 754, the method 750 comprises measuring a first current in the first side of the transformer and a first phase angle of the first current relative to the first AC voltage by the transformer tester. At block 756, the method 750 comprises exciting the first side of the transformer by the transformer tester with a second excitation output, wherein the second excitation output is a second AC voltage and a second frequency.

At block 758, the method 750 comprises measuring a second current in the first side of the transformer and a second phase angle of the second current relative to the second AC voltage by the transformer tester. At block 760, the method 750 comprises determining eddy current losses in the transformer by the transformer tester based on the first AC voltage, the first frequency, the first current, the first phase angle, the second AC voltage, the second frequency, the second current, and the second phase angle.

At block 762, the method 750 comprises applying a first DC voltage by the transformer tester to the first side of the transformer. At block 764, the method 750 comprises periodically sampling and storing values of a third current in the first side of the transformer by the transformer tester. At block 766, the method 750 comprises periodically determining and storing values of a magnetic flux of the transformer by the transformer tester by integrating the first DC voltage over time.

At block 768, the method 750 comprises determining a first time at which the magnetic flux of the transformer reaches a threshold by the transformer tester. At block 770, the method 750 comprises, at the first time, applying a second DC voltage by the transformer tester to the first side of the transformer, wherein the second DC voltage is the negative of the first DC voltage.

At block 772, the method 750 comprises, after applying the second DC voltage to the first side of the transformer, identifying a second time when the third current is determined to be the negative of the value of the third current at the first time by the transformer tester. At block 774, the method 750 comprises determining hysteresis losses of the transformer based on the stored values of the third current and the stored values of the magnetic flux stored between the first time and the second time.

In an embodiment, the method steps 752 through 760 can be performed to determine eddy current losses and not perform steps 762 through 774. In an embodiment, the method steps 762 through 774 can be performed to determine hysteresis losses and not perform steps 752 through 760. Summing the eddy current losses and the hysteresis losses provides the no-load losses of the transformer under test. The method 750 can be performed on a single phase of the transformer 110, on two phases of the transformer 110 concurrently, or on three phases of the transformer 110 concurrently.

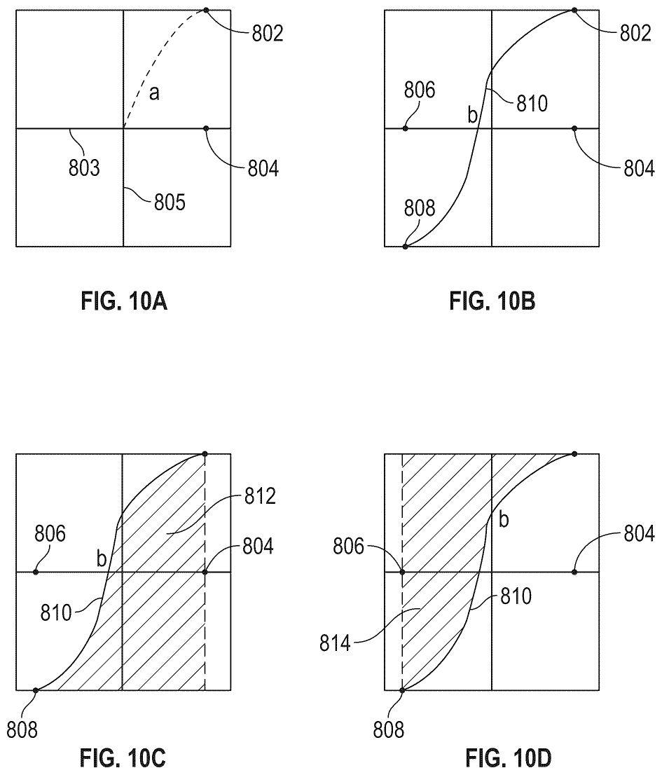

Turning now to FIG. 10A, FIG. 10B, FIG. 10C, and FIG. 10D, and with continued reference to FIG. 9B, further details for determining hysteresis losses of the transformer based on the stored values of the current in the first side of the transformed and based on the stored values of the magnetic flux are discussed. In FIG. 10A, a graph is shown having a horizontal x-axis 803 and a vertical y-axis 805. The intersection of the axes 803, 805 represents a zero value of both axes. The x-axis 803 represents a current in amps in the first side of the transformer 110 referred to as the third current in method 750 described with reference to FIG. 9B above; the y-axis 805 represents a magnetic flux in units of volt-seconds (e.g., the integration of volts as time passes) in the transformer 110 referred to as magnetic flux in the method 750 described with reference to FIG. 9B above. The trace a (a curve representing points corresponding to the sampled values of the third current in the first side of the transformer 110 and magnetic flux in the transformer 110) represents the values of both the third current in the first side of the transformer 110 and the magnetic flux in the transformer starting from the initial application of the first DC voltage to the first side of the transformer 110 at block 762 of method 750. When the magnetic flux in the transformer 110 reaches the threshold at 802, the third current in the first side of the transformer has the value indicated at position 804 on the x-axis.

In FIG. 10B, the curve 810 corresponds to the sampled values of the third current in the first side of the transformer 110 and the magnetic flux in the transformer 110 from the time the second DC voltage is applied to the first side of the transformer 110 at block 770 (corresponding to the upper right beginning point of the curve 810) to the time the third current reaches the value 806 that corresponds to the negative of the value of the third current at position 804 (e.g., block 772 of method 750). The point 808 is the point on the curve 810 where the current reaches the value 806. The transformer tester 192, 194 can sample the values of third current in the first side of the transformer 110 and the voltage in the first side of the transformer 110 periodically and store these values. The transformer tester 192, 194 can also calculate the magnetic flux as the product of time with the voltage and store values of magnetic flux. In an embodiment, the transformer tester 192, 194 stores only the values of magnetic flux during the processing of blocks 770 through 772 and does not store the values of voltage. In an embodiment, the transformer tester 192, 194 samples the third current and voltage and/or magnetic flux at a rate between 1000 samples per second and 50000 times per second, at a rate between 2000 samples per second and 35000 samples per second, at a rate between 4000 samples per second and 25000 samples per second, at a rate between 6000 samples per second and 20000 samples per second, at a rate between 8000 and 16000 samples per second, or at a rate between 9000 and 12000 samples per second. In an embodiment, the transformer tester 192, 194 samples the third current and voltage and/or magnetic flux at a rate between 600 samples per second and 200000 samples per second.

It will be appreciated that the curve 810 can be represented mathematically as a sequence of coordinate pairs—where each coordinate pair comprises a value of the third current in the first side of the transformer 110 and a value of the magnetic flux in the transformer 110. While drawn as a continuous line in FIG. 10B, FIG. 10C, and FIG. 10D, it is understood that the curve 810 can be abstracted as a series of separated coordinate pairs—or points—disposed on the curve 810. Thus, the curve 810 can be stored in a memory of the transformer tester 192, 194 (e.g., in a memory of the controller 160 or in a memory of the microcontroller 165).

In FIG. 10C, an area 812 under the curve 810 is indicated by cross-hatching. In FIG. 10D, an area 814 above the curve 810 is indicated by cross-hatching. Again, these areas 812, 814 can be analytically determined by the controller 160 from the stored coordinate pairs and/or stored values of the third current and the magnetic flux. These areas are indications of power (e.g., proportional to the product of volts times the third current). By subtracting area 814 from area 812, an indication of the hysteresis losses in the transformer 110 can be determined.

It will be appreciated that a transformer may be a linear device with respect to its phases, thus it may transform the applied (three-phase) voltage linearly. That is, its response may be the same for an applied voltage with respect to its positive, negative, and zero components. Thus, any additional distortion—that is additional negative sequence component—indicates a lack of transformer linearity between phases. Lack of linearity would indicate a problem with the transformer.

Thus, an additional negative sequence component determined during the ratio test (comparison of the excitation voltage with respect to the response voltage) may indicate a problem in the ratio of one of the phases (incorrect number of active turns, shorted turns, excessive core losses). With the negative sequence component having a magnitude and a phase angle, it is the magnitude that may indicate the severity of the problem, while the phase angle points to the phase of the transformer with the problem.

Similarly, a negative sequence component determined from the excitation current may indicate a problem with the magnetic circuit (excessive loss, shorted turns). Again, the magnitude may indicate the severity of the problem, while the phase angle may point to the phase of the transformer with the problem.

### Additional Disclosure

The following are non-limiting, specific embodiments in accordance with the present disclosure.

A first embodiment, which is a winding resistance meter comprises a switching matrix; a measurement circuit; a test output circuit; and a processor coupled to the switching matrix, the measurement circuit, and the test output circuit, wherein the processor configured to: configure the switching matrix in a first configuration; apply a first excitation signal to a first side of a transformer under test; measure a first winding resistance generated in response to the first excitation signal; configure the switching matrix in a second configuration; apply a second excitation signal to the second side of the transformer under test; and measure a second winding resistance generated in response to the second excitation signal.

A second embodiment, which is the winding resistance meter of the first embodiment, wherein the first excitation signal comprises a single-phase signal.

A third embodiment, which is the winding resistance meter of the first embodiment, wherein the first excitation signal comprises a three-phase signal.

A fourth embodiment, which is the winding resistance meter of any of the first through the third embodiment, wherein the second excitation signal comprises a single-phase signal.

A fifth embodiment, which is the winding resistance meter of any of the first through the third embodiment, wherein the second excitation signal comprises a three-phase signal.

A sixth embodiment, which is the winding resistance meter of any of the first through the third embodiment, wherein the first excitation signal is applied and direct current (DC) voltage is measured on the second side of the transformer under test to determine transformer saturation.

A seventh embodiment, which is the winding resistance meter of any of the first through the third embodiment, wherein the second excitation signal is applied when the transformer under test is saturated by the first excitation signal.

An eighth embodiment, which is the winding resistance meter of any of the first through the third embodiment or the seventh embodiment, wherein the second excitation signal is removed after obtaining winding resistance measurements, while keeping the first excitation signal applied.

A ninth embodiment, which is the winding resistance meter of any of the first through the eighth embodiment, wherein a third excitation signal is applied when the transformer under test is saturated by the first excitation signal.

A tenth embodiment, which is the winding resistance meter of any of the first through third embodiment, wherein the first excitation signal is applied and DC current is measured on the second side of the transformer under test to determine induced current during a tap change.

An eleventh embodiment, which is a method of measuring transformer winding resistance by a transformer winding resistance meter comprising configuring a switching matrix of the transformer winding resistance meter by a processor of the transformer winding resistance meter to a first configuration; applying a first excitation signal by the processor to a first side of a transformer under test, measuring a first winding resistance generated in response the first excitation signal by the processor; configuring the switching matrix by the processor in a second configuration; applying a second excitation signal to the second side of the transformer under test; and measuring a second winding resistance generated in response to the second excitation signal.

A twelfth embodiment, which is the method of the eleventh embodiment, wherein the first excitation signal comprises a single-phase

A thirteenth embodiment, which is the method of the eleventh embodiment, wherein the first excitation signal comprises a three-phase signal.

A fourteenth embodiment, which is the method of any of the eleventh through the thirteenth embodiment, wherein the second excitation signal comprises a single-phase signal.

A fifteenth embodiment, which is the method of any of the eleventh through the thirteenth embodiment, wherein the second excitation signal comprises a three-phase signal.

A sixteenth embodiment, which is the method of any of the eleventh through the thirteenth embodiment, wherein the first excitation signal is applied and direct current (DC) voltage is measured on the second side of the transformer under test to determine a transformer saturation level.

A seventeenth embodiment, which is the method of any of the eleventh through the fifteenth embodiment, wherein the second excitation signal is applied when the transformer under test is sufficiently saturated by the first excitation signal.

An eighteenth embodiment, which is the method of any of the eleventh through the seventeenth embodiment, wherein the second excitation signal is removed after obtaining winding resistance measurements, while keeping the first excitation signal applied.

A nineteenth embodiment, which is the method of any of the eleventh through the eighteenth embodiment, wherein a third excitation signal is applied when the transformer is saturated by the first excitation signal.

A twentieth embodiment, which is the method of any of the eleventh through the thirteenth embodiment, wherein the first excitation signal is applied and DC current is measured on the second side of the transformer to determine induced current during a tap change.

A twenty-first embodiment, which is a transformer turns ratio meter comprising a switching matrix; a measurement circuit; a test output circuit; and a processor coupled to the switching matrix, measurement circuit, and test output circuit, wherein the processor is configured to: configure the switching matrix in a first configuration; apply a first excitation signal to a first side of a transformer; to measure a first voltage generated in response to the first excitation signal at a second side of the transformer; to determine a first turns ratio estimate based upon the first voltage and first excitation signal; to configure the switching matrix in a second configuration; to apply a second excitation signal to the second side of the transformer; to measure a second voltage generated in response to the second excitation signal at the first side of the transformer; to determine a second turns ratio estimate based upon the second voltage and second excitation signal; and to determine a turns ratio of the transformer based upon the first turns ratio estimate and the second turns ratio estimate.

A twenty-second embodiment, which is the meter of the twenty-first embodiment, wherein the first excitation signal comprises a single-phase signal.

A twenty-third embodiment, which is the meter of the twenty-first embodiment, wherein the first excitation signal comprises a three-phase signal.

A twenty-fourth embodiment, which is the meter of any of the twenty-first through the twenty-third embodiment, wherein the processor is further configured to determine the second excitation signal based upon the first turns ratio estimate.

A twenty-fifth embodiment, which is the meter of any of the twenty-first through the twenty-fourth embodiment, wherein the processor configured to determine the turns ratio of the transformer comprises the processor configured to determine an average of the first turns ratio estimate and the second turns ratio estimate.

A twenty-sixth embodiment, which is the meter of any of the twenty-first through the twenty-fifth embodiment, wherein the processor is further configured to apply a third excitation signal to the first side of the transformer; to measure a third voltage generated in response to the third excitation signal at the second side of the transformer; and to determine an excitation loss of the transformer based upon the first voltage and the third voltage.

A twenty-seventh embodiment, which is the meter of any of the twenty-sixth embodiment, wherein the turns ratio of the transformer is determined further based upon the excitation loss.

A twenty-eighth embodiment, which is the meter of any of the twenty-first through twenty-seventh embodiment, wherein the first excitation signal comprises a first square-wave excitation and the second excitation signal comprises a second square-wave excitation.

A twenty-ninth embodiment, which is the meter of any of the twenty-first through twenty-eight embodiment, wherein the first voltage comprises a step-down voltage and the second voltage comprises a step-up voltage.

A thirtieth embodiment, which is a method to measure a transformer turns ratio of a transformer under test, comprising configuring a switching matrix of a transformer turns ratio meter in a first configuration; applying a first excitation signal to a first side of the transformer under test; measuring a first voltage generated in response to the first excitation signal at a second side of the transformer under test; determining a first turns ratio estimate based upon the first voltage and first excitation signal; configuring the switching matrix in a second configuration; applying a second excitation signal to the second side of the transformer; measuring a second voltage generated in response to the second excitation signal at the first side of the transformer; determining a second turns ratio estimate based upon the second voltage and second excitation signal; and determining a turns ratio of the transformer based upon the first turns ratio estimate and the second turns ratio estimate.

A thirty-first embodiment, which is the method of the thirtieth embodiment, wherein the first excitation signal comprises a single-phase signal.

A thirty-second embodiment, which is the method of the thirtieth embodiment, wherein the first excitation signal comprises a three-phase signal.

A thirty-third embodiment, which is the method of any of the thirtieth through thirty-second embodiment, further comprising determining the second excitation signal based upon the first turns ratio estimate.

A thirty-fourth embodiment, which is the method of any of the thirtieth through the thirty-third embodiment, wherein determining the turns ratio of the transformer under test comprises determining an average of the first turns ratio estimate and the second turns ratio estimate.

A thirty-fifth embodiment, which is the method of any of the thirtieth through the thirty-fourth embodiment, further comprising: applying a third excitation signal to the first side of the transformer under test; measuring a third voltage generated in response to the third excitation signal at the second side of the transformer under test; and determining an excitation loss of the transformer under test based upon the first voltage and the third voltage.

A thirty-sixth embodiment, which is the method of any of the thirtieth through the thirty-fifth embodiment, wherein the turns ratio of the transformer is further based upon the excitation loss.

A thirty-seventh embodiment, which is any of the thirtieth through the thirty-sixth embodiment, wherein the first excitation signal comprises a first square-wave excitation and the second excitation signal comprises a second square-wave excitation.

A thirty-eighth embodiment, which is any of the thirtieth through the thirty-seventy embodiment, wherein the first voltage comprises a step-down voltage and the second voltage comprises a step-up voltage.

A thirty-ninth embodiment, which is an impedance meter comprising a switching matrix; a measurement circuit; a test output circuit; and a processor coupled to the switching matrix, measurement circuit, and test output circuit, the processor configured to: configure the switching matrix in a first configuration; apply a first excitation signal to a first side of a transformer under test; measure a first voltage generated in response to the first excitation signal at a second side of the transformer under test; determine a first turns ratio estimate based upon the first voltage and first excitation signal; configure the switching matrix in a second configuration; apply a second excitation signal to the second side of the transformer under test; measure a second voltage generated in response to the second excitation signal at the first side of the transformer under test; determine a second turns ratio estimate based upon the second voltage and second excitation signal; determine a turns ratio of the transformer under test based upon the first turns ratio estimate and the second turns ratio estimate; configure the switching matrix in a third configuration; apply a third excitation signal to the second side of the transformer under test; measure third excitation voltage/current/phase in response to the third configuration; and determine the impedance of the transformer under test.

A fortieth embodiment, which is the meter of the thirty-ninth embodiment, wherein the first excitation signal comprises a single-phase signal.

A forty-first embodiment, which is the meter of the thirty-ninth embodiment, wherein the first excitation signal comprises a three-phase signal.

A forty-second embodiment, which is the meter of any of the thirty-ninth through forty-first embodiment, wherein the processor is further configured to determine the second excitation signal based upon the first turns ratio estimate.

A forty-third embodiment, which is the meter of any of the thirty-ninth through forty-second embodiment, wherein the processor configured to determine the turns ratio of the transformer comprises the processor configured to determine an average of the first turns ratio estimate and the second turns ratio estimate.

A forty-fourth embodiment, which is the meter of any of the thirty-ninth through forty-third embodiment, wherein the processor is further configured to: apply a fourth excitation signal to the first side of the transformer; measure a fourth voltage generated in response to the second excitation signal at the second side of the transformer; and determine an excitation loss of the transformer based upon the first voltage and the third voltage.

A forty-fifth embodiment, which is the meter of any of the thirty-ninth through forty-fourth embodiment, wherein the turns ratio of the transformer is further based upon the excitation loss.

A forty-sixth embodiment, which is the meter of any of the thirty-ninth through forty-fifth embodiment, wherein the first excitation signal comprises a first square-wave excitation and the second excitation signal comprises a second square-wave excitation.

A forty-seventh embodiment, which is the meter of any of the thirty-ninth through forty-fifth embodiment, wherein the first excitation signal comprises a first square-wave excitation and the second excitation signal comprises a second sinewave excitation.

A forty-eighth embodiment, which is the meter of any of the thirty-ninth through forty-seventh embodiment, wherein the first voltage comprises a step-down voltage and the second voltage comprises a step-up voltage.

A forty-ninth embodiment, which is the meter of any of the thirty-ninth through the forty-eighth embodiment, wherein the third excitation signal comprises a single-phase signal.

A fiftieth embodiment, which is the meter of any of the thirty-ninth through the forty-eighth embodiment, wherein the third excitation signal comprises a three-phase signal.

A fifty-first embodiment, which is the meter of any of the thirty-ninth through the fiftieth embodiment, wherein the third voltage comprises a sinewave excitation.

A fifty-second embodiment, which is a method of measuring an impedance of a transformer under test, comprising configuring a switching matrix in a first configuration; applying a first excitation signal to a first side of the transformer under test; measuring a first voltage generated in response to the first excitation signal at a second side of the transformer under test; determining a first turns ratio estimate based upon the first voltage and first excitation signal; configuring the switching matrix in a second configuration; applying a second excitation signal to the second side of the transformer under test; measuring a second voltage generated in response to the second excitation signal at the first side of the transformer under test; determining a second turns ratio estimate based upon the second voltage and second excitation signal; determining a turns ratio of the transformer based upon the first turns ratio estimate and the second turns ratio estimate; configuring the switching matrix in a third configuration; applying a third excitation signal to the second side of the transformer under test; measuring third excitation voltage/current/phase in response to the third configuration; and determining the impedance of the transformer under test.

A fifty-third embodiment, which is the method of the fifty-second embodiment, wherein the first excitation signal comprises a single-phase signal.

A fifty-fourth embodiment, which is the method of the fifty-second embodiment, wherein the first excitation signal comprises a three-phase signal.

A fifty-fifth embodiment, which is the method of any of the fifty-second through fifty-fourth embodiment, further comprising determining the second excitation signal based upon the first turns ratio estimate.

A fifty-sixth embodiment, which is the method of any of the fifty-second through fifty-fifth embodiment, wherein determining the turns ratio of the transformer comprises determining an average of the first turns ratio estimate and the second turns ratio estimate.

A fifty-seventh embodiment, which is the method of any of the fifty-second through fifty-fifth embodiment, further comprising: applying a fourth excitation signal to the first side of the transformer; measuring a fourth voltage generated in response to the fourth excitation signal at the second side of the transformer; and determining an excitation loss of the transformer based upon the first voltage and the third voltage.

A fifty-eighth embodiment, which is the method of any of the fifty-second through fifty-seventh embodiment, wherein the turns ratio of the transformer is further based upon the excitation loss.

A fifty-ninth embodiment, which is the method of any of the fifty-second through fifty-eighth embodiment, wherein the first excitation signal comprises a first square-wave excitation and the second excitation signal comprises a second square-wave excitation.

A sixtieth embodiment, which is the method of any of the fifty-second through fifty-ninth embodiment, wherein the first voltage comprises a step-down voltage and the second voltage comprises a step-up voltage.

A sixty-first embodiment, which is the method of any of the fifty-second through sixtieth embodiment, wherein the third excitation signal comprises a single-phase signal.

A sixty-second embodiment, which is the method of any of the fifty-second through sixtieth embodiment, wherein the third excitation signal comprises a three-phase signal.

A sixty-third embodiment, which is the method of any of the fifty-second through sixty-second embodiment, wherein the third voltage comprises a sine-wave excitation.

A sixty-fourth embodiment, which is a no-load loss meter comprising: a switching matrix; a measurement circuit; a test output circuit; and a processor coupled to the switching matrix, measurement circuit, and test output circuit, the processor configured to: configure the switching matrix in a first configuration; apply a first excitation signal to a first side of a transformer under test; measure a first voltage generated in response to the first excitation signal at a second side of the transformer under test; determine a first turns ratio estimate based upon the first voltage and first excitation signal; configure the switching matrix in a second configuration; apply a second excitation signal to the second side of the transformer under test; measure a second voltage generated in response to the second excitation signal at the first side of the transformer under test; determine a second turns ratio estimate based upon the second voltage and second excitation signal; and determine a turns ratio of the transformer under test based upon the first turns ratio estimate and the second turns ratio estimate; configure the switching matrix in a third configuration; apply a third excitation signal to the second side of the transformer under test; measure third excitation voltage/current/phase in response to the third configuration; and determine the impedance of the transformer under test; configure the switching matrix in a fourth configuration; apply a fourth excitation signal to the primary side of the transformer under test; measure the fourth excitation voltage/current/phase in response to the fourth configuration; and determine the no-load losses of the transformer under test.

A sixty-fifth embodiment, which is the meter of the sixty-fourth embodiment, wherein the first excitation signal comprises a single-phase signal.

A sixty-sixth embodiment, which is the meter of the sixty-fourth embodiment, wherein the first excitation signal comprises a three-phase signal.

A sixty-seventh embodiment, which is the meter of any of the sixty-fourth through sixty-sixth embodiment, wherein the processor is further configured to determine the second excitation signal based upon the first turns ratio estimate.

A sixty-eighth embodiment, which is the meter of any of the sixty-fourth through sixty-seventh embodiment, wherein the processor configured to determine the turns ratio of the transformer comprises the processor configured to determine an average of the first turns ratio estimate and the second turns ratio estimate.

A sixty-ninth embodiment, which is the meter of any of the sixty-fourth through the sixty-eighth embodiment, wherein the processor is further configured to: apply a fifth excitation signal to the first side of the transformer under test; measure a fifth voltage generated in response to the second excitation signal at the second side of the transformer under test; and determine an excitation loss of the transformer under test based upon the first voltage and the third voltage.

A seventieth embodiment, which is the meter of any of the sixty-fourth through the sixty-ninth embodiment, wherein the turns ratio of the transformer is further based upon the excitation loss.

A seventy-first embodiment, which is the meter of any of the sixty-fourth through the seventieth embodiment, wherein the first excitation signal comprises a first square-wave excitation and the second excitation signal comprises a second square-wave excitation.

A seventy-second embodiment, which is the meter of any of the sixty-fourth through the seventieth embodiment, wherein the first excitation signal comprises a first square-wave excitation and the second excitation signal comprises a second sinewave excitation.

A seventy-third embodiment, which is the meter of any of the sixty-fourth through seventy-second embodiment, wherein the first voltage comprises a step-down voltage and the second voltage comprises a step-up voltage.

A seventy-fourth embodiment, which is the meter of any of the sixty-fourth though seventy-third embodiment, wherein the third excitation signal comprises a single-phase signal.

A seventy-fifth embodiment, which is the meter of any of the sixty-fourth through seventy-third embodiment, wherein the third excitation signal comprises a three-phase signal.

A seventy-sixth embodiment, which is the meter of any of the sixty-fourth through seventy-fifth embodiment, wherein the third voltage comprises a sinewave excitation.

A seventy-seventh embodiment, which is the meter of any of the sixty-fourth through seventy-sixth embodiment, wherein the fourth voltage comprises a direct current (DC) excitation.

A seventy-eighth embodiment, which a method of measuring a no-load loss of a transformer under test comprising configuring a switching matrix in a first configuration; applying a first excitation signal to a first side of a transformer; measuring a first voltage generated in response to the first excitation signal at a second side of the transformer; determining a first turns ratio estimate based upon the first voltage and first excitation signal; configuring the switching matrix in a second configuration; applying a second excitation signal to the second side of the transformer; measuring a second voltage generated in response to the second excitation signal at the first side of the transformer; determining a second turns ratio estimate based upon the second voltage and second excitation signal; and determining a turns ratio of the transformer based upon the first turns ratio estimate and the second turns ratio estimate; configuring the switching matrix in a third configuration; applying a third excitation signal to the second side of the transformer; measuring third excitation voltage/current/phase in response to the third configuration; and determining the impedance of the transformer; configuring the switching matrix in a fourth configuration; applying a fourth excitation signal to the primary side of the transformer; measuring the fourth excitation voltage/current/phase in response to the fourth configuration; and determining the no-load losses of the transformer.

A seventy-ninth embodiment, which is the method of the seventy-eighth embodiment, wherein the first excitation signal comprises a single-phase signal.

An eightieth embodiment, which is the method of the seventy-eighth embodiment, wherein the first excitation signal comprises a three-phase signal.

An eighty-first embodiment, which is the method of any of the seventy-eighth through eightieth embodiment, further comprising determining the second excitation signal based upon the first turns ratio estimate.

An eighty-second embodiment, which is the method of any of the seventy-eighth through eighty-first embodiment, wherein determining the turns ratio of the transformer comprises determining an average of the first turns ratio estimate and the second turns ratio estimate.

An eighty-third embodiment, which is the method of any of the seventy-eighth through eighth-second embodiment, further comprising: applying a fourth excitation signal to the first side of the transformer; measuring a fourth voltage generated in response to the fourth excitation signal at the second side of the transformer; and determining an excitation loss of the transformer based upon the first voltage and the third voltage.

An eighty-fourth embodiment, which is the method of any of the seventy-eighth through eighty-third embodiment, wherein the turns ratio of the transformer is further based upon the excitation loss.

An eighty-fifth embodiment, which is the method of any of the seventy-eighth through eighty-fourth embodiment, wherein the first excitation signal comprises a first square-wave excitation and the second excitation signal comprises a second square-wave excitation.

An eighty-sixth embodiment, which is the method of any of the seventy-eighth through eighty-fifth embodiment, wherein the first voltage comprises a step-down voltage and the second voltage comprises a step-up voltage.

An eighty-seventh embodiment, which is the method of any of the seventy-eighth through eighty-sixth embodiment, wherein the third excitation signal comprises a single-phase signal.

An eighty-eighth embodiment, which is the method of any of the seventy-eighth though eighty-sixth embodiment, wherein the third excitation signal comprises a three-phase signal.

An eighty-ninth embodiment, which is the method of any of the seventy-eighth through eighty-eighth embodiment, wherein the third voltage comprises a sine-wave excitation.

A ninetieth embodiment, which is the method of any of the seventy-eighth through eighty-ninth embodiment, wherein the fourth voltage comprises a direct current (DC) excitation.

A ninety-first embodiment, which is a symmetrical component meter comprising: a switching matrix; a measurement circuit; a test output circuit; and a processor coupled to the switching matrix, measurement circuit, and test output circuit, the processor configured to: configure the switching matrix in a first configuration; apply a first excitation signal to a first side of a transformer under test; measure a first voltage generated in response to the first excitation signal at a second side of the transformer under test; determine a first turns ratio estimate based upon the first voltage and first excitation signal; configure the switching matrix in a second configuration; apply a second excitation signal to the second side of the transformer under test; measure a second voltage generated in response to the second excitation signal at the first side of the transformer under test; determine a second turns ratio estimate based upon the second voltage and second excitation signal; and determine a turns ratio of the transformer under test based upon the first turns ratio estimate and the second turns ratio estimate.

A ninety-second embodiment, which is the meter of the ninety-first embodiment, wherein the first excitation signal comprises a single-phase signal.

A ninety-third embodiment, which is the meter of the ninety-first embodiment, wherein the first excitation signal comprises a three-phase signal.

A ninety-fourth embodiment, which is the meter of any of the ninety-first though ninety-third embodiment, wherein the processor is further configured to determine the second excitation signal based upon the first turns ratio estimate.

A ninety-fifth embodiment, which is the meter of any of the ninety-first through ninety-fourth embodiment, wherein the processor configured to determine the turns ratio of the transformer comprises the processor configured to determine an average of the first turns ratio estimate and the second turns ratio estimate.

A ninety-sixth embodiment, which is the meter of any of the ninety-first through ninety-fourth embodiment, wherein the processor is further configured to: apply a fourth excitation signal to the first side of the transformer; measure a fourth voltage generated in response to the second excitation signal at the second side of the transformer; and determine an excitation loss of the transformer based upon the first voltage and the third voltage.

A ninety-seventh embodiment, which is the meter of any of the ninety-first through ninety-fourth embodiment, wherein the turns ratio of the transformer is further based upon the excitation loss.

A ninety-eighth embodiment, which is the meter of any of the ninety-first through ninety-seventh embodiment, wherein the first excitation signal comprises a first square-wave excitation and the second excitation signal comprises a second square-wave excitation.

A ninety-ninth embodiment, which is the meter of any of the ninety-first through ninety-seventy embodiment, wherein the first excitation signal comprises a first square-wave excitation and the second excitation signal comprises a second sine-wave excitation.

A one hundredth embodiment, which is the meter of any of the ninety-first through ninety-ninth embodiment, wherein the first voltage comprises a step-down voltage and the second voltage comprises a step-up voltage.

A one hundred and first embodiment, which is the meter of any of the ninety-first through one hundredth embodiment, wherein the third excitation signal comprises a single-phase signal.

A one hundred and second embodiment, which is the meter of any of the ninety-first through one hundredth embodiment, wherein the third excitation signal comprises a three-phase signal.

A one hundred and third embodiment, which is the meter of any of the ninety-first through one hundred and second embodiment, wherein the third voltage comprises a sine-wave excitation.

A one hundred and fourth embodiment, which is the meter of any of the ninety-first through one hundred and third embodiment, wherein the turns ratio estimate and excitation current losses are further analyzed and broken into negative, positive, and zero sequence components.

A one hundred and fifth embodiment, which is the meter of any of the ninety-first through one hundred and fourth embodiment, wherein the negative, positive, and zero sequence turns ratio and excitation current losses are analyzed to provide distortion index and core imbalance.

A one hundred and sixth embodiment, which is a method of measuring symmetrical components of a transformer under test, the method comprising: configuring a switching matrix in a first configuration; applying a first excitation signal to a first side of the transformer under test; measuring a first voltage generated in response to the first excitation signal at a second side of the transformer under test; determining a first turns ratio estimate based upon the first voltage and first excitation signal; configuring the switching matrix in a second configuration; applying a second excitation signal to the second side of the transformer under test; measuring a second voltage generated in response to the second excitation signal at the first side of the transformer under test; determining a second turns ratio estimate based upon the second voltage and second excitation signal; and determining a turns ratio of the transformer based upon the first turns ratio estimate and the second turns ratio estimate.

A one hundred and seventh embodiment, which is the method of the one hundred and sixth embodiment, wherein the first excitation signal comprises a single-phase signal.

A one hundred and eighth embodiment, which is the method of the one hundred and sixth embodiment, wherein the first excitation signal comprises a three-phase signal.

A one hundred and ninth embodiment, which is the method of any of the one hundred and sixth embodiment through one hundred and eighth embodiment, further comprising determining the second excitation signal based upon the first turns ratio estimate.

A one hundred and tenth embodiment, which is the method of any of the one hundred and sixth through one hundred and ninth embodiment, wherein determining the turns ratio of the transformer under test comprises determining an average of the first turns ratio estimate and the second turns ratio estimate.

A one hundred and eleventh embodiment, which is the method of any of the one hundred and sixth through one hundred and tenth embodiment, further comprising: applying a fourth excitation signal to the first side of the transformer under test; measuring a fourth voltage generated in response to the fourth excitation signal at the second side of the transformer under test; and determining an excitation loss of the transformer under test based upon the first voltage and the third voltage.

A one hundred and twelfth embodiment, which is the method of any of the one hundred and sixth through one hundred and eleventh embodiment, wherein the turns ratio of the transformer is further based upon the excitation loss.

A one hundred and thirteenth embodiment, which is the method of any of the one hundred and sixth through one hundred and twelfth embodiment, wherein the first excitation signal comprises a first square-wave excitation and the second excitation signal comprises a second square-wave excitation.

A one hundred and fourteenth embodiment, which is the method of any of the one hundred and sixth through one hundred and thirteenth embodiment, wherein the first voltage comprises a step-down voltage and the second voltage comprises a step-up voltage.

A one hundred and fifteenth embodiment, which is the method of any of the one hundred and sixth through one hundred and fourteenth embodiment, wherein the third excitation signal comprises a single-phase signal.

A one hundred and sixteenth embodiment, which is the method of any of the one hundred and sixth through one hundred and fourteenth embodiment, wherein the third excitation signal comprises a three-phase signal.

A one hundred and seventeenth embodiment, which is the method of any of the one hundred and sixth through one hundred and sixteenth embodiment, wherein the third voltage comprises a sine-wave excitation.

While several embodiments have been provided in the present disclosure, it should be understood that the disclosed systems and methods may be embodied in many other specific forms without departing from the spirit or scope of the present disclosure. The present examples are to be considered as illustrative and not restrictive, and the intention is not to be limited to the details given herein. For example, the various elements or components may be combined or integrated in another system or certain features may be omitted or not implemented.

Also, techniques, systems, subsystems, and methods described and illustrated in the various embodiments as discrete or separate may be combined or integrated with other systems, modules, techniques, or methods without departing from the scope of the present disclosure. Other items shown or discussed as directly coupled or communicating with each other may be indirectly coupled or communicating through some interface, device, or intermediate component, whether electrically, mechanically, or otherwise. Other examples of changes, substitutions, and alterations are ascertainable by one skilled in the art and could be made without departing from the spirit and scope disclosed herein.

What is claimed is:

1. A transformer windings resistance meter comprising:
a switching matrix;
a measurement circuit;
a test output circuit; and
a processor coupled to the switching matrix, measurement circuit, and test output circuit, the processor configured to:
configure the switching matrix in a first configuration,
apply a first energization output to a first side of a transformer,
while continuing to apply the first energization output to the first side of the transformer, apply a second energization output to a first phase of a second side of the transformer,
while continuing to apply the first energization output to the first side of the transformer and while continuing to apply the second energization output to the first phase of the second side of the transformer, measure a first voltage and a first current on the first phase of the second side of the transformer,
based on the first voltage and the first current, determine a first winding resistance of the first phase of the second side of the transformer,
while continuing to apply the first energization output to the first side of the transformer, remove the second energization output from the first phase of the second side of the transformer,
while continuing to apply the first energization output to the first side of the transformer and after removing the second energization output from the first phase of the second side of the transformer, apply a third energization output to a second phase of the second side of the transformer,
while continuing to apply the first energization output to the first side of the transformer and continuing to apply the third energization output to the second phase of the second side of the transformer, measure a second voltage and a second current on the second phase of the second side of the transformer, and
based on the second voltage and the second current, determine a second winding resistance of the second phase of the second side of the transformer.

2. The transformer windings resistance meter of claim 1, wherein the processor is further configured to:
while continuing to apply the first energization output to the first side of the transformer, remove the third energization output from the second phase of the second side of the transformer,
while continuing to apply the first energization output to the first side of the transformer and after removing the third energization output from the second phase of the second side of the transformer, apply a fourth energization output to a third phase of the second side of the transformer,
while continuing to apply the first energization output to the first side of the transformer and continuing to apply the fourth energization output to the third phase of the second side of the transformer, measure a third voltage and a third current on the third phase of the second side of the transformer, and
based on the third voltage and the third current, determine a third winding resistance of the third phase of the second side of the transformer.

3. The transformer windings resistance meter of claim 2, wherein the processor is further configured to:
after removing the second energization output from the first phase of the second side of the transformer and before applying the third energization output to the second phase of the second side of the transformer, configure the switching matrix in a second configuration, and
after removing the third energization output from the second phase of the second side of the transformer and before applying the fourth energization output to the third phase of the second side of the transformer, configure the switching matrix in a third configuration.

4. The transformer windings resistance meter of claim 2, wherein the processor is further configured to:
configure the switching matrix in a fourth configuration,
apply a fifth energization output to the second side of a transformer,
while continuing to apply the fifth energization output to the second side of the transformer, apply a sixth energization output to a first phase of the first side of the transformer,
while continuing to apply the fifth energization output to the second side of the transformer and while continuing to apply the sixth energization output to the first phase of the first side of the transformer, measure a fourth voltage and a fourth current on the first phase of the first side of the transformer,
based on the fourth voltage and the fourth current, determine a fourth winding resistance of the first phase of the first side of the transformer,
while continuing to apply the fifth energization output to the second side of the transformer, remove the sixth energization output from the first phase of the first side of the transformer,
while continuing to apply the fifth energization output to the second side of the transformer and after removing the sixth energization output from the first phase of the first side of the transformer, apply a seventh energization output to a second phase of the first side of the transformer,
while continuing to apply the fifth energization output to the second side of the transformer and continuing to apply the seventh energization output to the second phase of the first side of the transformer, measure a fifth voltage and a fifth current on the second phase of the first side of the transformer,
based on the fifth voltage and the fifth current, determine a fifth winding resistance of the second phase of the first side of the transformer,
while continuing to apply the fifth energization output to the second side of the transformer, remove the seventh energization output from the second phase of the first side of the transformer,
while continuing to apply the fifth energization output to the second side of the transformer and after removing the seventh energization output from the second phase of the first side of the transformer, apply an eighth energization output to a third phase of the first side of the transformer,
while continuing to apply the fifth energization output to the second side of the transformer and continuing to apply the eighth energization output to the third phase of the first side of the transformer, measure a sixth voltage and a sixth current on the third phase of the first side of the transformer, and
based on the sixth voltage and the sixth current, determine a sixth winding resistance of the third phase of the first side of the transformer.

5. The transformer windings resistance meter of claim 4, wherein the processor is further configured to:
after removing the sixth energization output from the first phase of the first side of the transformer and before applying the seventh energization output to the second phase of the first side of the transformer, configuring the switching matrix to a fifth configuration; and
after removing the seventh energization output from the second phase of the first side of the transformer and before applying the eighth energization output to the third phase of the first side of the transformer, configure the switching matrix to a sixth configuration.

6. The transformer windings resistance meter of claim 1, wherein the first energization output is applied to a first phase of the first side of the transformer.

7. The transformer windings resistance meter of claim 1, wherein the first energization output is applied to two or more phases of the first side of the transformer.

8. The transformer windings resistance meter of claim 1, wherein the processor is further configured to
while continuing to apply the first energization output to the first side of the transformer and after removing the second energization output from the first phase of the second side of the transformer, apply a ninth energization output to a third phase of the second side of the transformer,
while continuing to apply the first energization output to the first side of the transformer, continuing to apply the third energization output to the second phase of the second side of the transformer, and continuing to apply the ninth energization output to the third phase of the second side of the transformer, measure a seventh voltage and a seventh current on the third phase of the second side of the transformer, and
based on the seventh voltage and the seventh current, determine a third winding resistance of the third phase of the second side of the transformer.

9. A transformer windings impedance meter comprising:
a switching matrix;
a plurality of field effect transistors (FETs);
a measurement circuit;
a test output circuit; and
a processor coupled to the switching matrix, the plurality of FETs, the measurement circuit, and the test output circuit, the processor configured to:
configure the switching matrix in a first configuration,
apply a short circuit to a first side of a transformer, where the short circuit is completed through at least one of the plurality of FETs,
apply a first alternating current (AC) excitation to a second side of the transformer,
while continuing to apply the first AC excitation to the second side of the transformer, measure a first voltage and a first current in the second side of the transformer, and
determine an impedance of the second side of the transformer based on the first voltage and the first current.

10. The transformer windings impedance meter of claim 9, wherein the processor further measures a phase angle between the first voltage and the first current in the second side of the transformer and wherein the processor determines the impedance of the second side of the transformer based on the first voltage, based on the first current, and further based on the phase angle between the first voltage and the first current in the second side of the transformer.

11. The transformer windings impedance meter of claim 8, wherein the short circuit is applied to a first phase of the first side of the transformer and the first AC excitation signal is applied to a first phase of the second side of the transformer and wherein determining the impedance of the second side of the transformer is based on the first voltage and the first current in the first phase of the transformer.

12. The transformer windings impedance meter of claim 11, wherein the processor is configured to:
apply a short circuit to a second phase of the first side of the transformer, where the short circuit is completed through at least one of the plurality of FETs,
apply a second alternating current (AC) excitation to a second phase of the second side of the transformer,
while continuing to apply the second AC excitation to the second phase of the second side of the transformer, measure a second voltage and a second current in the second phase of the second side of the transformer, and
determine an impedance of the second phase of the second side of the transformer based on the second voltage and the second current.

13. The transformer windings impedance meter of claim 9, wherein determining the impedance of the transformer is further based on a turns ratio of the transformer.

14. The transformer windings impedance meter of claim 9, wherein the processor is configured to determine a virtual inductance of a set of leads extending from the transformer windings impedance meter to the first side of the transformer, wherein determining the impedance of the second side of the transformer is further based on the virtual inductance of the set of leads extending from the transformer windings impedance meter to the first side of the transformer.

15. The transformer windings impedance meter of claim 14, wherein the processor is configured to:
determine losses in the set of leads extending from the transformer windings impedance meter to the first side of the transformer based on a voltage in the leads extending from the transformer windings impedance meter to the first side of the transformer, a current in the leads extending from the transformer windings impedance meter to the first side of the transformer, and a phase angle between the current in the leads and the voltage in the leads;
determine transformer excitation losses based on a product of a voltage of the AC excitation and the current of the AC excitation and a phase angle of the current of the AC excitation relative to the voltage of the AC excitation; and
determine active losses of the transformer based on subtracting the losses in the set of leads extending from the transformer windings impedance meter to the first side of the transformer from the transformer excitation losses.

16. A method for measuring no-load losses in a transformer, comprising:
exciting a first side of the transformer by a transformer tester with a first excitation output, where the first excitation output is a first alternating current (AC) voltage and at a first frequency, wherein a second side of the transformer is open;
measuring a first current in the first side of the transformer and a first phase angle of the first current relative to the first AC voltage by the transformer tester;
exciting the first side of the transformer by the transformer tester with a second excitation output, wherein the second excitation output is a second AC voltage and a second frequency;
measuring a second current in the first side of the transformer and a second phase angle of the second current relative to the second AC voltage by the transformer tester; and
determining eddy current losses in the transformer by the transformer tester based on the first AC voltage, the first frequency, the first current, the first phase angle, the second AC voltage, the second frequency, the second current, and the second phase angle.

17. The method of claim 16, wherein the first AC voltage is less than two thirds of full rated voltage of the first side of the transformer and wherein the second AC voltage is less than two thirds of the first AC voltage.

18. The method of claim 16, further comprising:
applying a first DC voltage by the transformer tester to the first side of the transformer;
periodically sampling and storing values of a third current in the first side of the transformer by the transformer tester;
periodically determining and storing values of a magnetic flux of the transformer by the transformer tester by integrating the first DC voltage over time;
determining a first time at which the magnetic flux of the transformer reaches a threshold by the transformer tester;
at the first time, applying a second DC voltage by the transformer tester to the first side of the transformer, wherein the second DC voltage is a negative of the first DC voltage;
after applying the second DC voltage to the first side of the transformer, identifying a second time when the third current is determined to be the negative of the value of the third current at the first time by the transformer tester; and
determining hysteresis losses of the transformer based on the stored values of the third current and the stored values of the magnetic flux stored between the first time and the second time.
